(19) United States
(12) Patent Application Publication
(10) Pub. No.: US 2026/0169583 A1
(43) Pub. Date: Jun. 18, 2026

(54) Display Apparatus

(71) Applicant: LG Display Co., Ltd., Seoul (KR)

(72) Inventors: Jeonghoon Lee, Paju-si (KR); Yoonnara Jang, Paju-si (KR)

(21) Appl. No.: 19/374,831

(22) Filed: Oct. 30, 2025

(30) Foreign Application Priority Data
Dec. 16, 2024 (KR) 10-2024-0187536

(51) Int. Cl. G06F 3/041; G06F 3/044; G09G 3/32; H10H 29/39

(52) U.S. Cl. CPC G06F 3/04164; G06F 3/0412; G06F 3/0446; H10H 29/39; G06F 2203/04108; G09G 3/32; G09G 2330/021; G09G 2354/00

(57) ABSTRACT

The present disclosure provides a display apparatus capable of sensing a touch by a user's contact or a touch by a user's non-contact. The display apparatus according to one or more embodiments of the present disclosure comprises a substrate including a display area, a first touch electrode part disposed in an intermediate portion of the display area, a second touch electrode part disposed along an edge portion of the display area, and a driving circuit part configured to sense a contact touch of a user through the first touch electrode part and to sense a non-contact touch of the user through the second touch electrode part.

### CROSS-REFERENCE TO RELATED APPLICATION

This application claims the priority of Republic of Korea Patent Application No. 10-2024-0187536 filed on Dec. 16, 2024, which is hereby incorporated by reference in its entirety.

### BACKGROUND

### Field

The present disclosure relates to a display apparatus.

### Description of the Related Art

The display apparatus is applied to various electronic apparatuses such as televisions (TVs), mobile phones, laptops, and tablets.

The display apparatus includes an organic light emitting display apparatus that emit light by themselves and a liquid crystal display apparatus that require a separate light source.

Recently, a display apparatus including a light emitting device has attracted attention as a next-generation display apparatus. The light emitting device is made of an inorganic material, not an organic material. Accordingly, compared to the liquid crystal display apparatus or the organic light emitting display apparatus, the display apparatus including the light emitting device has a faster lighting speed, excellent luminous efficiency, and displays an image having high luminance.

Electronic devices using a display apparatus as a display screen provide a user interface of a touch screen type, for convenience of a user input. Display apparatuses capable of touch interface processing are advancing to provide more various functions. For example, display apparatuses including a touch panel which is capable of touch sensing based on a touch pen (or a stylus pen) as well as finger touch sensing based on a finger, are being widely used.

### SUMMARY

An aspect of the present disclosure is directed to providing a display apparatus capable of sensing a touch by a user's contact or a touch by a user's non-contact.

An aspect of the present disclosure is directed to providing a display apparatus capable of simplifying the structure and low-power driving.

Additional features, advantages, and aspects of the present disclosure are set forth in part in the present disclosure and will also be apparent from the present disclosure or may be learned by practice of the inventive concepts provided herein. Other features, advantages, and aspects of the present disclosure may be realized and attained by the descriptions provided in the present disclosure, or derivable therefrom, and claims hereof as well as the appended drawings.

To achieve these and other advantages and aspects of the present disclosure, as embodied and broadly described herein, in one or more aspects, a display apparatus according to one or more embodiments of the present disclosure comprises a substrate including a display area, a first touch electrode part disposed in an intermediate portion of the display area, a second touch electrode part disposed along an edge portion of the display area, and a driving circuit part configured to sense a contact touch of a user through the first touch electrode part and to sense a non-contact touch of the user through the second touch electrode part.

Details of other exemplary embodiments will be included in the detailed description of the disclosure and the accompanying drawings.

A display apparatus according to one or more embodiments of the present disclosure may be capable of sensing a touch by a user's contact or a touch by a user's non-contact.

In the display apparatus according to one or more embodiments of the present disclosure, touch sensitivity (or touch performance) at an edge portion of a display area may be improved.

A display apparatus according to one or more embodiments of the present disclosure may have a simplified structure and be capable of low-power driving.

In the display apparatus according to one or more embodiments of the present disclosure, power consumption may be reduced, and thus, ESG (environmental, social, and governance) may be implemented.

According to one or more embodiments of the present disclosure, instead of directly forming pixel circuits for driving the light emitting devices configured in each of the plurality of sub-pixels on a substrate, the structure of the display apparatus may be simplified, and high-efficiency driving and low-power driving may be achieved by mounting a pixel driving circuit (or pixel driving integrated circuit), in which the pixel circuits are integrated, on the substrate.

Other systems, methods, features and advantages will be, or will become, apparent to one with skill in the art upon examination of the following figures and detailed description. It is intended that all such additional systems, methods, features and advantages be included within this description, be within the scope of the present disclosure, and be protected by the following claims. Nothing in this section should be taken as a limitation on those claims. Further aspects and advantages are discussed below in conjunction with aspects of the disclosure.

It is to be understood that both the foregoing description and the following description of the present disclosure are exemplary and explanatory and are intended to provide further explanation of the disclosure as claimed.

### BRIEF DESCRIPTION OF THE DRAWINGS

The accompanying drawings, which are included to provide a further understanding of the disclosure, are incorporated in and constitute a part of this disclosure, illustrate aspects and embodiments of the disclosure and together with the description serve to explain principles of the disclosure. However, the technical features of the present embodiments are not limited to those shown in the specific drawings, and the features disclosed in each drawing may be combined to form a new embodiment.

FIG. 1 is an exploded perspective view illustrating a display apparatus according to one or more embodiments of the present disclosure.

FIG. 2 is a plan view of a display apparatus according to one or more embodiments of the present disclosure.

FIG. 3 is an enlarged view of the display apparatus according to one or more embodiments of the present disclosure.

FIG. 4 is a diagram illustrating a circuit structure according to one or more embodiments of the present disclosure.

FIGS. 5 to 7 are plan views of a display apparatus according to one or more embodiments of the present disclosure.

FIG. 8 is a cross-sectional view taken along line I-I′ illustrated in FIG. 2 or FIG. 3.

FIG. 9 is a cross-sectional view of a first light emitting device according to one or more embodiments of the present disclosure.

FIG. 10 is a diagram illustrating first and second touch electrode parts according to one or more embodiments of the present disclosure.

FIG. 11 is a diagram illustrating one pixel block illustrated in FIG. 10.

FIG. 12 is a diagram illustrating a display period and a touch sensing period of a display apparatus according to one or more embodiments of the present disclosure.

FIG. 13 is a diagram illustrating a touch sensing method in a display apparatus according to one or more embodiments of the present disclosure.

FIG. 14 is a diagram illustrating a pixel driving circuit according to one or more embodiments of the present disclosure.

FIG. 15 is a diagram illustrating a driving integrated circuit according to one or more embodiments of the present disclosure.

FIG. 16 is a diagram illustrating a first signal switching part, a first line connection part, and a first touch sensing part illustrated in FIG. 15.

FIG. 17 is a diagram illustrating a second signal switching part, a second line connection part, and a second touch sensing part illustrated in FIG. 15.

FIG. 18 is a diagram illustrating first and second touch electrode parts according to one or more embodiments of the present disclosure.

FIGS. 19 to 22 are diagrams illustrating an apparatus to which a display apparatus is applied according to one or more embodiments of the present disclosure.

Throughout the drawings and the detailed description, unless otherwise described, the same drawing reference numerals should be understood to refer to the same elements, features, and structures. The sizes, lengths, and thicknesses of layers, regions and elements, and depiction of thereof may be exaggerated for clarity, illustration, and convenience.

### DETAILED DESCRIPTION

Advantages and features of the present disclosure, and implementation methods thereof, are clarified through the aspects described with reference to the accompanying drawings. The present disclosure may, however, be embodied in different forms and should not be construed as limited to the example aspects set forth herein. Rather, these example aspects are examples and are provided so that this disclosure may be thorough and complete to assist those skilled in the art to understand the inventive concepts without limiting the protected scope of the present disclosure.

A shape, a size, a ratio, an angle, and a number disclosed in the drawings for describing embodiments of the present disclosure are merely an example, and thus, the present disclosure is not limited to the illustrated details. Like reference numerals refer to like elements throughout. In the following description, when the detailed description of the relevant known function or configuration is determined to unnecessarily obscure the important point of the present disclosure, the detailed description will be omitted. In a situation where “comprise,” “have,” and “include” described in the present disclosure are used, another part may be added unless “only” is used. The terms of a singular form can include plural forms unless referred to the contrary.

Any implementation described herein as an “example” is not necessarily to be construed as preferred or advantageous over other implementations.

In construing an element, the element is construed as including an error range although there is no explicit description.

In describing a position relationship, for example, when a position relation between two parts is described as “on”, “over”, “under”, “next”, and “adjacent to” or the like, one or more other parts may be located between the two parts unless a more limiting term, such as “immediate(ly)”, “direct(ly)”, or “close(ly)” is used.

In describing a temporal relationship, when the temporal order is described as, for example, “after”, “subsequent”, “next”, “before”, or the like, a case that is not consecutive or not sequential can be included and thus one or more other events can occur therebetween, unless a more limiting term, such as “immediate(ly)” or “direct(ly)” is used.

It is understood that, although the terms “first,” “second,” or the like may be used herein to describe various elements, these elements should not be limited by these terms, for example, to any particular order, precedence, or number of elements. These terms are used only to distinguish one element from another. Therefore, the first element described below may be understood as the second element within the scope of the technical idea of the present disclosure.

In describing elements of the present disclosure, the terms “first”, “second”, “A”, “B”, “(a)”, “(b)”, or the like may be used. These terms are intended to identify the corresponding element from the other element, and these are not used to define the essence, basis, order, or number of the elements.

For the expression that an element is “connected”, “coupled”, “contact”, or “attach” to another element, the element may not only be directly connected, coupled, or contacted to another element, but also be indirectly connected, coupled, contacted, or attached to another element with one or more intervening elements interposed between the elements, unless otherwise specified.

For the expression that an element is “contacts” or “overlaps” with another element, the element can not only directly contact, overlap, or the like with another element, but also indirectly contact or overlap with another element with one or more intervening elements disposed or interposed between the elements, unless otherwise specified.

The expression of a first element, a second elements “and/or” a third element should be understood as one of the first, second and third elements or as any or all combinations of the first, second and third elements. By way of example, A, B and/or C can refer to only A; only B; only C; any or some combination of A, B, and C; or all of A, B, and C.

The term “at least one” should be understood as including any and all combinations of one or more of the associated listed items. For example, the meaning of “at least one of a first element, a second element, and a third element” compasses the combination of all three listed elements, combinations of any two of the three elements, as well as each individual element, the first element, the second element, or the third element.

“a first direction”, “a second direction”, “a third direction”, “X-axis direction”, “Y-axis direction”, and “Z-axis direction” should not be construed by a geometric relation only of a mutual vertical relation and may have broader directionality within the range that elements of the present disclosure may act functionally.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

Rather, these embodiments may be provided so that this disclosure may be sufficiently thorough and complete to assist those skilled in the art to fully understand the scope of the present disclosure. Furthermore, the present disclosure is only defined by scopes of claims.

Features of various embodiments of the present disclosure may be partially or overall coupled to or combined with each other and may be variously inter-operated with each other and driven technically as those skilled in the art can sufficiently understand. The embodiments of the present disclosure may be carried out independently from each other or may be carried out together in co-dependent relationship.

Hereinafter, example embodiments of a sound apparatus according to the present disclosure will be described in detail with reference to the accompanying drawings. For convenience of description, a scale of each of elements illustrated in the accompanying drawings differs from a real scale, and thus, is not limited to a scale illustrated in the drawings.

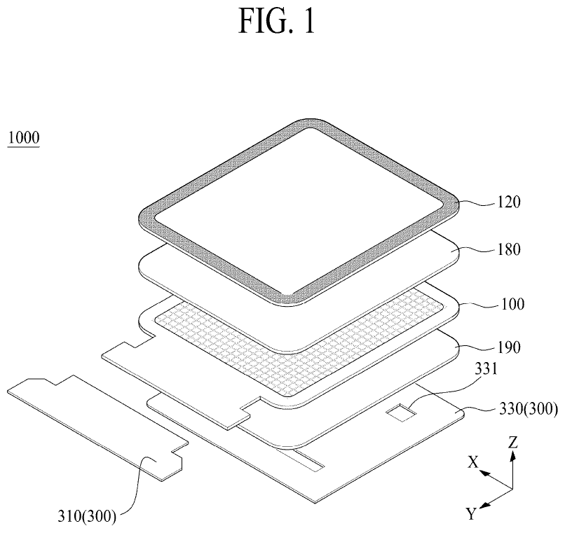

FIG. 1 is an exploded perspective view illustrating a display apparatus according to one or more embodiments of the present disclosure.

Referring to FIG. 1, a display apparatus 1000 according to one or more embodiments of the present disclosure may include a display panel 100 and a driving circuit part 300.

The display panel 100 may be configured to implement information, video, and/or images provided to a user on a screen. For example, the display panel 100 may be a light emitting display panel including a plurality of pixels having a light emitting device.

The display panel 100 according to one or more embodiments may include a substrate including a display area. The display area may include a plurality of pixels. For example, the display panel 100 or the substrate may further include a non-display area surrounding the display area.

The display panel 100 may be configured to sense a user touch. For example, the display panel 100 may be configured to sense the user touch through a touch pen or a finger.

The display panel 100 may include a touch electrode part configured to sense the user touch. The touch electrode part may be embedded in the display panel 100 or may be implemented (or configured) by electrodes (or metal layers) configuring the display panel 100 (or a plurality of pixels). The touch electrode part according to one or more embodiments may include a first touch electrode part disposed (or configured) in an intermediate portion (or a middle portion) including a central portion (or a central portion) of the display area, and a second touch electrode part disposed (or configured) in an edge portion of the display area. For example, in the display area, the edge portion may be disposed to surround the intermediate portion.

The driving circuit part (or a display driving circuit part) 300 may be configured to be electrically connected to the display panel 100 (or substrate). The driving circuit part 300 may be configured to generate signals required to display (or implement) an image on the display panel 100 and supply the signals to the display panel 100.

The driving circuit part (or a display driving circuit part) 300 may be configured to sense a user's contact touch through the first touch electrode part and to sense a user's non-contact touch through the second touch electrode part. For example, the driving circuit part 300 may be configured to sense the user's contact touch through the first touch electrode part in the first touch mode and to sense the user's non-contact touch through the second touch electrode part in the second touch mode. For example, the non-contact touch may be a hover touch, a gesture touch, a floating touch, or an air touch. For example, the first touch mode may be a contact touch mode or a normal touch mode. The second touch mode may be a non-contact touch mode, a hover touch mode, a gesture touch mode, a floating touch mode, or an air touch mode.

The driving circuit part 300 may be configured to sense the contact touch corresponding to a change in capacitance in the first touch electrode part based on a self-capacitance method in the first touch mode, but is not limited thereto. For example, the driving circuit part 300 may be configured to sense the contact touch corresponding to a change in capacitance in the first touch electrode part based on a mutual capacitance method in the first touch mode. The driving circuit part 300 may be configured to sense the non-contact touch corresponding to a change in capacitance between the first touch electrode part and the second touch electrode part based on the mutual capacitance method in the second touch mode.

The driving circuit part 300 may be configured to apply an auxiliary driving signal to the second touch electrode part in the first touch mode. For example, the auxiliary driving signal may be any one of a constant direct-current (DC) voltage, a ground voltage, and a touch driving signal, but is not limited thereto. For example, when an auxiliary driving signal of the ground voltage is applied to the second touch electrode part in the first touch mode, a decrease in touch sensitivity (or touch performance) caused by ambient noise may be minimized, at least reduced or prevented. For example, when an auxiliary driving signal corresponding to or identical to a touch driving signal is applied to the second touch electrode part in the first touch mode, touch sensitivity (or touch performance) at the edge portion of the display area AA may be improved. In the first touch mode, the second touch electrode part may be maintained in an electrically floating state.

The driving circuit part 300 may include a flexible circuit board 310 and a printed circuit board 330.

The flexible circuit board 310 and the printed circuit board 330 may be disposed at a lower portion of the display panel 100. The flexible circuit board 310 and the printed circuit board 330 may be disposed at least one side edge portion of the display panel 100. One side of the flexible circuit board 310 may be attached to the display panel 100, and the other side of the flexible circuit board 310 may be attached to the printed circuit board 330. The flexible circuit board 310 may be a flexible film.

The printed circuit board 330 may include at least one hole 331, but is not limited thereto. An internal component that sense ambient light or temperature, or the like, which may be provided to a plurality of sensors, may be disposed in a region corresponding to the at least one hole 331. For example, the internal component may include an ambient light sensor or a temperature sensor, or the like, but is not limited thereto. For example, the at least one hole 331 may be a transmission hole or the like, but is not limited thereto.

The display apparatus 1000 according to one or more embodiments of the present disclosure may further include a cover member 120 and a supporting substrate 190.

The cover member 120 may be disposed over the display panel 100. The cover member 120 may be a member to protect the display panel 100. The cover member 120 may be made of a transparent material. For example, the cover member 120 may be a cover window or cover glass.

The supporting substrate 190 may be disposed at a rear surface of the display panel 100. The supporting substrate 190 may be configured to reinforce the rigidity of the display panel 100. For example, the supporting substrate 190 may be made of a plastic or metal material. The supporting substrate 190 may be a back plate.

A portion of the display panel 100 may be bent to surround side surfaces (or lateral surfaces) of the supporting substrate 190 and may be disposed at a rear surface of the supporting substrate 190.

The supporting substrate 190 may be disposed between the display panel 100 and the printed circuit board 330. For example, the flexible circuit board 310 and the printed circuit board 330 may be disposed at the rear surface of the supporting substrate 190.

The display apparatus 1000 according to one or more embodiments of the present disclosure may further include a polarizing layer 180. The polarizing layer 180 may be disposed over the display panel 100. The polarizing layer 180 may be disposed (or interposed) between the display panel 100 and the cover member 120. The polarizing layer 180 may be configured to prevent or reduce light generated from an external light source from entering an interior of the display panel 100 and affecting light emitting devices or the like.

The polarizing layer 180 may attach to the display panel 100 by using an adhesive layer. The adhesive layer 185 may be disposed (or interposed) between the polarizing layer 180 and the cover member 120, and may attach the cover member 120 to the polarizing layer 180. The adhesive layer 185 may include an optically cleared adhesive, an optically cleared resin, or a pressure sensitive adhesive, or the like.

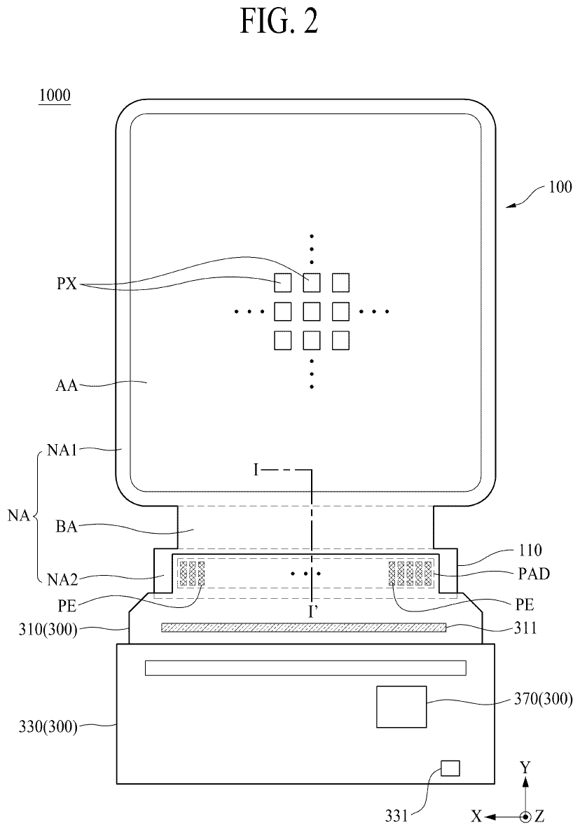

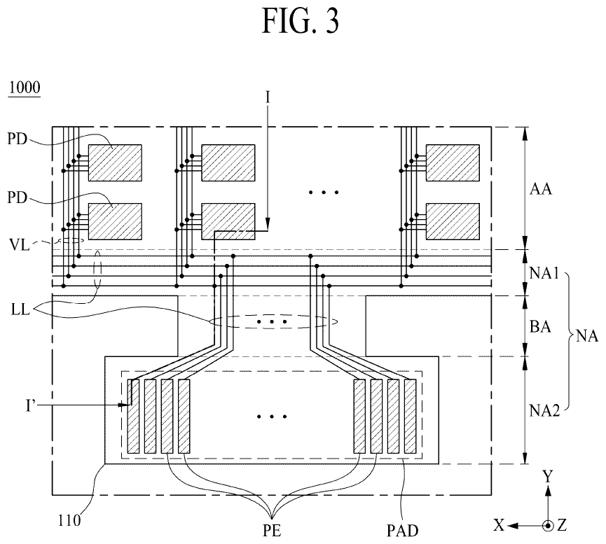

FIG. 2 is a plan view of a display apparatus according to one or more embodiments of the present disclosure, and FIG. 3 is an enlarged view of the display apparatus according to one or more embodiments of the present disclosure.

Referring to FIGS. 1 to 3, the display apparatus 1000 may include the display panel 100, a flexible circuit board 310, and a printed circuit board 330.

The display panel 100 may include a substrate 110. The substrate 110 may be a member configured to support the other components of the display apparatus 1000. For example, the substrate 110 may be made of glass or resin, or the like. In addition, the substrate 110 may be made of a material having flexibility. For example, the substrate 110 may be made of a plastic material having flexibility, such as polyimide, or the like, but is not limited thereto.

The display panel 100 may include a display area AA and a non-display area NA. For example, the substrate 110 may include a display area AA and a non-display area NA.

The display area AA may be an area (or a screen) where an image is displayed. The display area AA may include a plurality of pixels PX. Each of the plurality of pixels PX may be composed of a plurality of sub-pixels. For example, each of the plurality of pixels PX may include a plurality of sub-pixels. Each of the plurality of sub-pixels may include a plurality of light emitting devices. The plurality of light emitting devices may be configured differently depending on the type of the display apparatus 1000. For example, when the display apparatus 1000 is an inorganic light emitting display apparatus, the light emitting device may be an LED (light emitting diode), a micro LED (micro light emitting diode), or a mini LED (mini light emitting diode), but is not limited thereto.

The display area AA may be configured in various shapes according to a design of the display apparatus 1000. For example, the display area AA may be configured in a rectangular shape with four corners formed in a round shape, but is not limited thereto. For another example, the display area AA may be configured in a rectangular shape with four corners formed in right-angled shape or a circular shape, or the like, but is not limited thereto.

Referring to FIG. 3, a plurality of pixel driving circuits PD may be disposed at the display area AA. The plurality of pixel driving circuits PD may be circuits for driving the light emitting devices of the plurality of sub-pixels. Each of the plurality of pixel driving circuits PD includes a plurality of transistors including a driving transistor and a storage capacitor, or the like, and may control light emitting operations of the plurality of light emitting devices by supplying a control signal, power, and a driving current to the light emitting devices of the plurality of sub-pixels. For example, each of the plurality of pixel driving circuits PD may be electrically connected to a power wiring (or power lines) disposed (or configured) at the display area AA, and a signal wiring (or signal lines) for controlling light emitting on/off and/or light emitting time of the light emitting devices. For example, each of the plurality of pixel driving circuits PD may be a microchip, a pixel driving chip, or a chipset, and may be a semiconductor packaging device having one fine size including a plurality of transistors and a storage capacitor. For example, each of the plurality of pixel driving circuits PD may be a driving driver manufactured using a MOSFET (Metal-oxide-silicon field effect transistor) manufacturing process on a semiconductor substrate, but is not limited thereto. The driving driver includes the plurality of pixel driving circuits PD and may drive the plurality of sub-pixels.

The non-display area NA may be an area surrounding the display area AA. The non-display area NA may be an area where an image is not displayed. The non-display area NA may include various wirings (or lines) and driving circuits or the like for driving the plurality of pixels PX disposed (or configured) at the display area AA. For example, the various wirings (or lines) and the driving circuits may be mounted at the non-display area NA, and a pad portion PAD which is connected to an integrated circuit and a printed circuit board or the like may be disposed at the non-display area NA, but is not limited thereto.

The non-display area NA may include a first non-display area NA1, a bending area BA, and a second non-display area NA2. For example, the first non-display area NA1 may be an area surrounding at least a portion of the display area AA. The bending area BA may be an area extending from at least one of a plurality of sides of the first non-display area NA1 and may be a bendable area. The second non-display area NA2 may be an area extending from the bending area BA and may have the pad portion PAD disposed therein. For example, the bending area BA may be in a bent state, and the remaining area of the substrate 110 excluding the bending area BA may be in a flat state. In this case, as the bending area BA is bent, the second non-display area NA2 may be located on a rear surface of the display area AA, but is not limited thereto.

A plurality of link lines LL may be disposed at the non-display area NA. The plurality of link lines LL may be lines that transmit various signals from one or more flexible circuit boards (or flexible films) 310 and the printed circuit boards 330 to the display area AA. The plurality of link lines LL may extend from a plurality of pad electrodes PE of the second non-display area NA2 toward the bending area BA and the first non-display area NA1, and may be electrically connected to a plurality of driving lines VL of the display area AA. The plurality of pixel driving circuits PD may be driven by receiving signals from the one or more flexible circuit boards (or flexible films) 310 and the printed circuit boards 330 through the driving lines VL of the display area AA and the link lines LL of the non-display area NA.

The plurality of driving lines VL, together with the plurality of link lines LL, may be lines for transmitting signals output from the flexible circuit board 310 and the printed circuit board 330 to the plurality of pixel driving circuits PD. The plurality of driving lines VL may be disposed at the display area AA and may be electrically connected to each of the plurality of pixel driving circuits PD. The plurality of driving lines VL may extend from the display area AA toward the non-display area NA and may be electrically connected to the plurality of link lines LL. Therefore, signals output from the flexible circuit board 310 and the printed circuit board 330 may be transmitted to each of the plurality of pixel driving circuits PD through the plurality of link lines LL and the plurality of driving lines VL.

As the bending area BA is bent, a portion of the plurality of link lines LL may be bent together.

The plurality of link lines LL may be configured in various shapes to reduce stress. At least a portion of the plurality of link lines LL disposed on the bending area BA may extend in the same direction as an extension direction of the bending area BA, or may extend in a direction different from the extension direction of the bending area BA to reduce stress. For example, when the bending area BA extends in one direction from the first non-display area NA1 toward the second non-display area NA2, the at least the portion of the link lines LL disposed on the bending area BA may extend in a direction inclined with respect to the one direction. Accordingly, in order to minimize or at least reduce stress concentrated on the plurality of link lines LL and cracks resulting therefrom, the shapes of the plurality of link lines LL may be formed in various shapes, but is not limited thereto.

A width of the second non-display area NA2 in which the plurality of pad electrodes PE are disposed may be wider than a width of the bending area BA in which only the plurality of link lines LL are disposed. In addition, a width of the display area AA in which the plurality of sub-pixels are disposed may be wider than the width of the bending area BA in which only the plurality of link lines LL are disposed. Although the width of the bending area BA is illustrated as being narrower than a width of other area of the substrate 110 in the drawings, a shape of the substrate 110 including the bending area BA may be exemplary, but is not limited thereto.

The pad portion PAD including the plurality of pad electrodes PE may be disposed at the second non-display area NA2. The one or more flexible circuit boards 310 may be attached or bonded to the pad portion PAD. The plurality of pad electrodes PE of the pad portion PAD mat be electrically connected to the one or more flexible circuit boards 310 and may transmit various signals (or power) received from the printed circuit board 330 and the flexible circuit board 310 to the plurality of pixel driving circuits PD of the display area AA.

The driving circuit may include a driving integrated circuit (or a display driving circuit or a timing controller) 311. For example, the driving circuit may be a data driving circuit and/or a gate driving circuit, but is not limited thereto. Wires to which a control signal for controlling the driving circuit is supplied may be disposed at the non-display area NA. For example, the control signal may include various timing signals including a clock signal, an input data enable signal, and synchronization signals, but is not limited thereto. The control signal may be received through the pad portion PAD. For example, link lines LL for transmitting the signals may be disposed at the non-display area NA. For example, the pad portion PAD may be electrically connected to the driving circuit of the driving circuit part 300.

The driving integrated circuit 311 may be mounted on the flexible circuit board 310. The driving integrated circuit 311 receives image data and a timing synchronization signal provided from a host control part, converts the image data into an emission signal for each sub-pixel and provides the converted emission signal to the plurality of pixel driving circuits PD, and controls a driving timing of each of the plurality of pixel driving circuits PD based on the timing synchronization signal.

The driving integrated circuit 311 may be configured to convert the image data for each sub-pixel into the emission signal for each sub-pixel based on a pulse width modulation PWM method. The emission signal may be a pulse width modulation signal that is varied in every frame, but is not limited thereto. For example, the emission signal may include a duty-on period for emitting light the light emitting device and a duty-off period for turning off the light emitting device. For example, the duty-on period of the emission signal may be set (or adjusted) by a gray scale corresponding to the pixel data.

The driving integrated circuit 311 may be configured to sense a user's contact touch through the first touch electrode part disposed (or configured) in the display area of the display panel 100, and to sense a user's non-contact touch through the second touch electrode part. For example, the driving integrated circuit 311 may be configured to sense the user's contact touch through the first touch electrode part in the first touch mode, and to sense the user's non-contact touch through the second touch electrode part in the second touch mode.

The driving integrated circuit 311 may be configured to apply a touch driving signal to the first touch electrode part in the first touch mode, generate first touch raw data (or contact touch raw data) corresponding to a change in capacitance based on the user's contact touch through the first touch electrode part, and to provide the generated first touch raw data to the host control part (or a host system circuit), but is not limited thereto. For example, the host control part may generate user touch information corresponding to contact touch coordinate data based on the first touch raw data provided from the driving integrated circuit 311, and may execute an application corresponding to the user touch information. For example, the driving integrated circuit 311 may be configured to generate user touch information corresponding to contact touch coordinate data based on the first touch raw data, and to provide the user touch information to the host control part.

The driving integrated circuit 311 may be configured to supply the touch driving signal to the first touch electrode part in the second touch mode, generate second touch raw data (or hover touch raw data) corresponding to a change in capacitance based on the user's non-contact touch through the second touch electrode part, and to provide the generated second touch raw data to the host control part, but is not limited thereto. For example, the host control part may generate a user's hover touch information (or gesture information) corresponding to hover touch data (or gesture data) based on the second touch raw data provided from the driving integrated circuit 311 and may execute an application corresponding to the user's hover touch information. For example, the driving integrated circuit 311 may be configured to generate the user's hover touch information corresponding to the contact touch coordinate data based on the second touch raw data, and to provide the user's hover touch information to the host control part.

The driving integrated circuit 311 may be configured so that a constant direct-current (DC) voltage (or ground voltage) is applied to the second touch electrode part in the first touch mode, but is not limited thereto. Accordingly, when a ground voltage is applied to the second touch electrode part in the first touch mode, a decrease in touch sensitivity (or touch performance) caused by ambient noise may be minimized, at least reduced or prevented. For example, the driving integrated circuit 311 may be configured so that an auxiliary driving signal corresponding to or identical to the touch driving signal is applied to the second touch electrode part in the first touch mode. Accordingly, touch sensitivity (or touch performance) at an edge portion of the second touch electrode unit part the first touch mode may be improved.

The flexible circuit board 310 may be a film in which various components are disposed on a base film having flexibility. For example, the driving integrated circuit 311 including one or more of a gate driver integrated circuit and a data driver integrated circuit may be disposed at the flexible circuit board 310, but is not limited thereto. The driving integrated circuit 311 may be a component that processes data and a driving signal for displaying an image. The flexible circuit board 310 may be attached or bonded on the plurality of pad electrodes PE through a conductive adhesive layer, but is not limited thereto.

The printed circuit board 330 is electrically connected to one or more flexible circuit boards 310 and may be a component that supplies signals to the driving integrated circuit 311. The printed circuit board 330 may be disposed at one side of the flexible circuit board 310 and may be electrically connected to the flexible circuit board 310. Circuit components such as a memory or various passive circuit elements or the like for supplying various signals to the driving integrated circuit 311 may be additionally disposed at the printed circuit board 330.

The driving circuit part 300 according to one or more embodiments of the present disclosure may further include a power generating integrated circuit 370.

The power generating integrated circuit (or power driving part or power generating part) 370 may be configured to generate and output various powers required for driving the display apparatus 1000. For example, the power generating integrated circuit 370 may be configured to generate and output a power voltage, a touch driving signal, a reference voltage, a cathode-on voltage, and a cathode-off voltage, or the like under the control of the driving integrated circuit 311 based on the input power. For example, the driving voltage may be a voltage for driving a driving circuit or an integrated circuit. The reference voltage may be a voltage for controlling (or determining) brightness (or luminance) of an image displayed in the display area AA or light emitted from the light emitting device. The cathode-on voltage may be a voltage for turning on (or emitting) the light emitting device. The cathode-off voltage may be a voltage for turning off the light emitting device. For example, the cathode-on voltage may be a first common voltage or a first low-potential power voltage, and the cathode-off voltage may be a second common voltage or a second low-potential power voltage, but is not limited thereto.

The power generating integrated circuit 370 according to one or more embodiments may be configured to generate and output the touch driving signal having one or more pulse signals through a pulse width modulation method. The touch driving signal output from the power generating integrated circuit 370 may be supplied to the pixel driving circuit PD through the driving integrated circuit 311.

The driving integrated circuit 311 may be configured to control voltages output from the power generating integrated circuit 370 based on the user touch information provided from the host control part. For example, when a user adjusts a screen brightness (or luminance) of the display apparatus 1000 through a contact touch or button operation, the driving integrated circuit 311 may be configured to provide reference voltage data and the cathode-off voltage data to the power generating integrated circuit 370 based on screen brightness data corresponding to the screen brightness according to the user operation (or setting). The power generating integrated circuit 370 may be configured to generate and output the reference voltage and the cathode-off voltage based on each of the reference voltage data and the cathode-off voltage data provided from the driving integrated circuit 311.

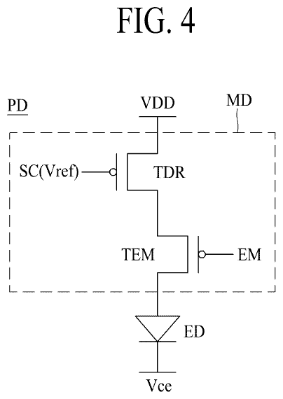

FIG. 4 is a diagram illustrating a circuit structure according to one or more embodiments of the present disclosure. FIG. 4 is a diagram illustrating one micro-driver included in each of the plurality of pixel driving circuits illustrated in FIG. 3.

In FIG. 4, one light emitting device ED is connected to one micro-driver MD as an example, but is not limited thereto. For example, 8 light emitting devices ED may be connected to the one micro-driver MD. For example, 8 light emitting devices ED in different lines (or horizontal lines or row lines) may be connected to the one micro-driver MD. In another example, 16 light emitting devices ED may be connected to the one micro-driver MD, or 32 light emitting devices ED or 64 light emitting devices ED may be simultaneously (or commonly) connected to the one micro-driver MD. For example, the micro-driver MD may be a sub-driver MD. For example, the light emitting device ED may be a micro light emitting device, a micro light emitting diode, or a micro light emitting diode chip. For example, the light emitting device ED may have a scale of 1 μm to 100 μm, but is not limited thereto.

The one micro-driver MD may be configured to apply an anode voltage (or a data current or a driving current) based on a scan signal (or reference voltage) and an emission signal to the light emitting device ED. The one micro-driver MD according to one or more embodiments of the present disclosure may include a driving transistor TDR and a light emitting transistor TEM, but is not limited thereto.

A high-potential power voltage VDD may be applied to a first electrode of the driving transistor TDR, a first electrode of the light emitting transistor TEM may be connected to a second electrode of the driving transistor TDR, and a scan signal SC may be applied from the driving integrated circuit to a gate electrode of the driving transistor TDR. The scan signal SC applied to the gate electrode of the driving transistor TDR is a direct-current (DC) power, and a fixed reference voltage Vref may be applied for every frame, but is not limited thereto. For example, the reference voltage Vref may be changed for one or more frames. For example, the reference voltage Vref may be adjusted (or varied) based on the screen brightness according to the user operation (or setting).

The second electrode of the driving transistor TDR may be connected to the first electrode of the light emitting transistor TEM, the light emitting device ED may be connected to a second electrode of the light emitting transistor TEM, and the emission signal EM may be applied from the driving integrated circuit to a gate electrode of the light emitting transistor TEM.

A first electrode of the light emitting device ED may be connected to the second electrode of the light emitting transistor TEM, and a second electrode of the light emitting device ED may be connected to a low-potential power line. For example, the first electrode of the light emitting device ED may be a first terminal, an anode electrode, or an anode terminal, and the second electrode of the light emitting device ED may be a second terminal, a cathode electrode, or a cathode terminal, but is not limited thereto. For example, the voltage applied from the light emitting transistor TEM to the first electrode of the light emitting device ED may be an anode voltage (or data voltage). For example, the voltage applied to the low-potential power line may be a cathode voltage Vce. For example, the voltage applied to the low-voltage power line may be a cathode-on voltage or a cathode-off voltage. For example, one or more of the cathode-on voltage and the cathode-off voltage may be varied (or adjusted). For example, one or more of the cathode-on voltage and the cathode-off voltage may be varied (or adjusted) according to the screen brightness according to user operation (or setting). For example, one or more of the cathode-on voltage and the cathode-off voltage may be varied (or adjusted) according to the reference voltage Vref.

Each of the driving transistor TDR and the light emitting transistor TEM may be an n-type transistor or a p-type transistor.

In the one micro-driver MD, the driving transistor TDR may be turned on by the scan signal SC applied from the pixel driving circuit PD, and the light emitting transistor TEM may be turned on by the emission signal EM applied from the pixel driving circuit PD. Accordingly, the driving current is applied to the light emitting device ED through the driving transistor TDR and the light emitting transistor TEM by the high-potential power voltage VDD applied to the first electrode of the driving transistor TDR, and thus, the light emitting device ED may emit light. For example, the light emitting device ED may emit light while the cathode-on voltage is applied to the low-potential power line, and may not emit light while the cathode-off voltage is applied to the low-potential power line.

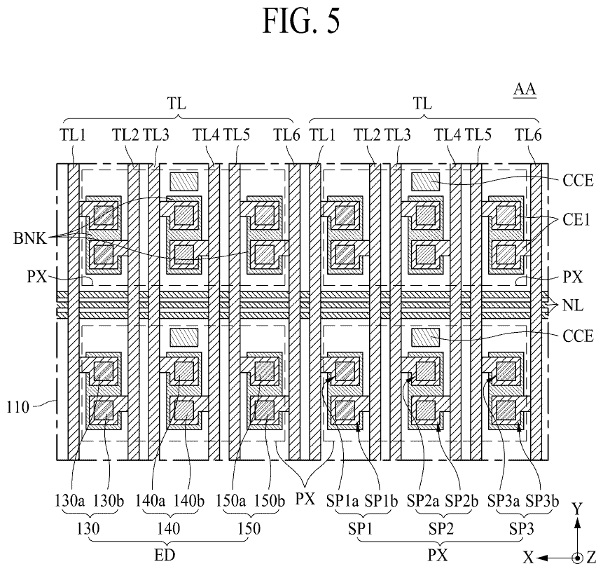

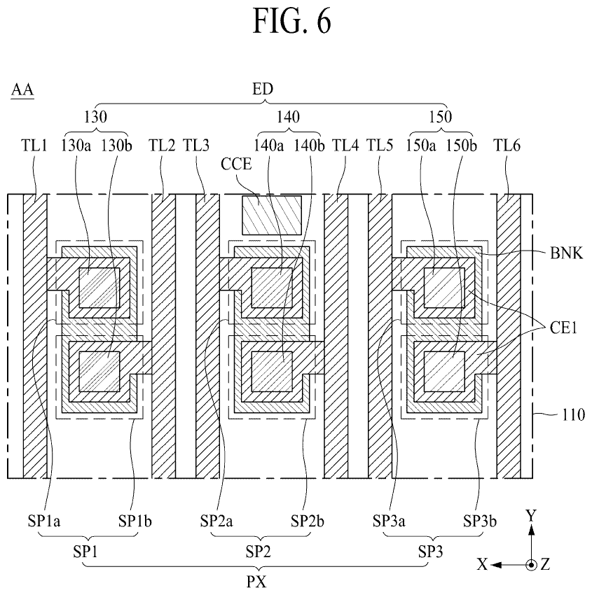

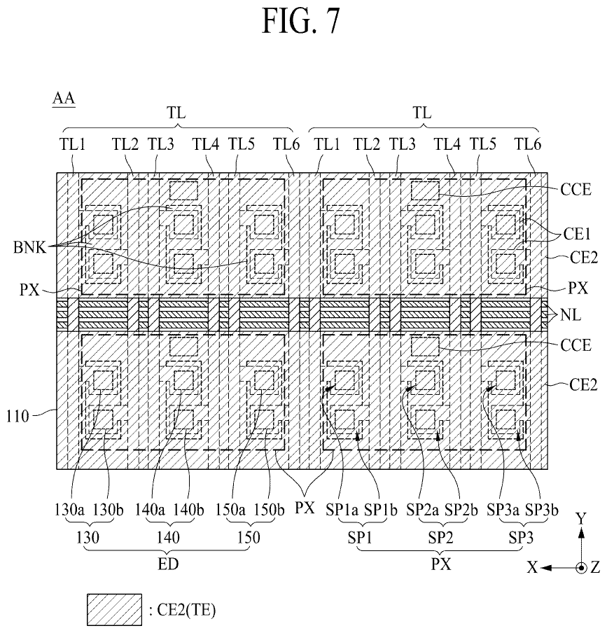

FIGS. 5 to 7 are plan views of a display apparatus according to one or more embodiments of the present disclosure. For example, FIG. 5 is an enlarged view of a display area including a plurality of pixels. For example, FIG. 6 is an enlarged view of a display area including one pixel. For example, FIG. 7 is an enlarged view of a display area including a plurality of pixels.

FIGS. 5 and 6 illustrate a plurality of signal lines TL, a plurality of communication lines NL, a plurality of first electrodes CE1, a plurality of banks BNK, and a plurality of light emitting devices ED, but is not limited thereto. FIG. 7 is an enlarged plan view in which the plurality of second electrodes CE2 are additionally disposed in FIG. 5, for convenience, an area overlapping the second electrodes CE2 is indicated with a dotted line.

Referring to FIGS. 5 to 7, a plurality of pixels PX composed of a plurality of sub-pixels may be disposed in a display area AA. Each of the plurality of sub-pixels includes a light emitting device ED and may independently emit light. The plurality of pixels (or sub-pixels) may be configured in a plurality of rows and a plurality of columns and may be disposed in a matrix form, but is not limited thereto.

The plurality of sub-pixels may include a first sub-pixel SP1, a second sub-pixel SP2, and a third sub-pixel SP3. For example, the plurality of sub-pixels may include the first sub-pixel SP1, the second sub-pixel SP2, and the third sub-pixel SP3 disposed along a row direction (or a first direction X). For example, any one sub-pixel of the first sub-pixel SP1, the second sub-pixel SP2, and the third sub-pixel SP3 may be a red sub-pixel, another sub-pixel may be a green sub-pixel, and the other sub-pixel may be a blue sub-pixel. The types of the plurality of sub-pixels are exemplary, but is not limited thereto.

Each of the plurality of pixels PX may include one or more first sub-pixels SP1, one or more second sub-pixels SP2, and one or more third sub-pixels SP3. For example, one pixel PX may include a pair of first sub-pixels SP1, a pair of second sub-pixels SP2, and a pair of third sub-pixels SP3.

The pair of first sub-pixels SP1 may be composed of a 1-1^{th} sub-pixel SP1a and a 1-2^{th} sub-pixel SP1b. The pair of second sub-pixels SP2 may be composed of a 2-1^{th} sub-pixel SP2a and a 2-2^{th} sub-pixel SP2b. The pair of third sub-pixels SP3 may be composed of a 3-1^{th} sub-pixel SP3a and a 3-2^{th} sub-pixel SP3b. For example, one pixel PX may include the 1-1^{th} sub-pixel SP1a, the 1-2^{th} sub-pixel SP1b, the 2-1^{th} sub-pixel SP2a, the 2-2^{th} sub-pixel SP2b, the 3-1^{th} sub-pixel SP3a, and the 3-2^{th} sub-pixel SP3b, but is not limited thereto.

The plurality of sub-pixels composing the one pixel PX may be variously arranged. For example, in the one pixel PX, the pair of first sub-pixels SP1 may be disposed in the same column, the pair of second sub-pixels SP2 may be disposed in the same column, and the pair of third sub-pixels SP3 may be disposed in the same column. The first sub-pixel SP1, the second sub-pixel SP2, and the third sub-pixel SP3 may be disposed in the same row. The number and arrangement of the plurality of sub-pixels composing the one pixel PX are exemplary, but is not limited thereto.

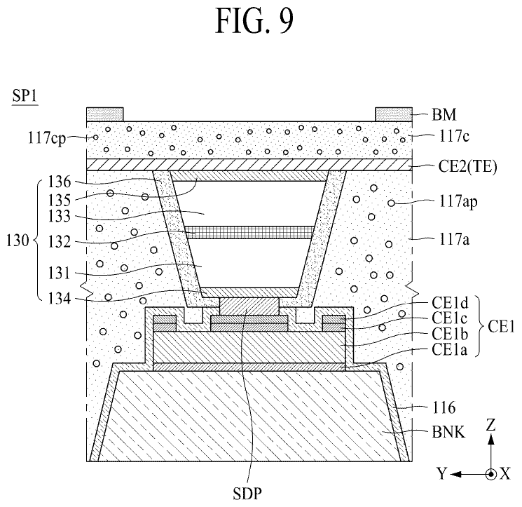

The plurality of signal lines TL may be disposed at an area between the plurality of sub-pixels. The plurality of signal lines TL may extend in a column direction (or a second direction Y) at the area between the plurality of sub-pixels. The plurality of signal lines TL may be lines that transmit an anode voltage from a pixel driving circuit (PD illustrated in FIG. 3 or a micro-driver MD) to the plurality of sub-pixels. For example, the plurality of signal lines TL may be electrically connected to the plurality of pixel driving circuits (PD illustrated in FIG. 3) and first electrodes CE1 of the plurality of sub-pixels. The anode voltage output from the pixel driving circuit (PD illustrated in FIG. 3) may be transmitted to the first electrodes CE1 of the plurality of sub-pixels through the plurality of signal lines TL. For example, the first electrode CE1 may be an electrode that is electrically connected to an anode electrode (134 illustrated in FIG. 9) of the light emitting device ED. Accordingly, the anode voltage from the signal line TL can be transmitted to the anode electrode (134 illustrated in FIG. 9) of the light emitting device ED through the first electrode CE1. For example, the first electrode CE1 may be a connection electrode, a connection electrode pattern, or a connection pattern.

Therefore, instead of forming a plurality of transistors and storage capacitors in each of the plurality of sub-pixels, a structure of the display apparatus 1000 may be simplified by using the pixel driving circuit (PD illustrated in FIG. 3) in which the plurality of pixel circuits are integrated. In addition, since the circuits disposed at each of the plurality of sub-pixels are integrated in one pixel driving circuit (PD illustrated in FIG. 3), high-efficiency and low-power driving may be possible.

The plurality of signal lines TL may include a first signal line TL1, a second signal line TL2, a third signal line TL3, a fourth signal line TL4, a fifth signal line TL5, and a sixth signal line TL6. Each of the first signal line TL1 and the second signal line TL2 may be electrically connected to each of the pair of first sub-pixels SP1. Each of the third signal line TL3 and the fourth signal line TL4 may be electrically connected to each of the pair of second sub-pixels SP2. Each of the fifth signal line TL5 and the sixth signal line TL6 may be electrically connected to each of the pair of third sub-pixels SP3.

The first signal line TL1 may be disposed at one side of the pair of first sub-pixels SP1, and the second signal line TL2 may be disposed at the other side of the pair of first sub-pixels SP1. The first signal line TL1 may be electrically connected to a first electrode CE1 of one first sub-pixel SP1 (for example, the 1-1^{th} sub-pixel SP1a) of the pair of first sub-pixels SP1. The second signal line TL2 may be electrically connected to a first electrode CE1 of the other first sub-pixel SP1 (for example, the 1-2^{th} sub-pixel SP1b) of the pair of first sub-pixels SP1.

The third signal line TL3 may be disposed at one side of the pair of second sub-pixels SP2, and the fourth signal line TL4 may be disposed at the other side of the pair of second sub-pixels SP2. For example, the third signal line TL3 may be disposed adjacent to the second signal line TL2. The third signal line TL3 may be electrically connected to a first electrode CE1 of one second sub-pixel SP2 (for example, the 2-1^{th} sub-pixel SP2a) of the pair of second sub-pixels SP2. The fourth signal line TL4 may be electrically connected to a first electrode CE1 of the other second sub-pixel SP2 (for example, the 2-2^{th} sub-pixel SP2b) of the pair of second sub-pixels SP2.

The fifth signal line TL5 may be disposed at one side of the pair of third sub-pixels SP3, and the sixth signal line TL6 may be disposed at the other side of the pair of third sub-pixels SP3. For example, the fifth signal line TL5 may be disposed adjacent to the fourth signal line TL4. The sixth signal line TL6 may be disposed adjacent to the first signal line TL1 connected to the adjacent pixel PX. The fifth signal line TL5 may be electrically connected to a first electrode CE1 of one third sub-pixel SP3 (for example, the 3-1^{th} sub-pixel SP3a) of the pair of third sub-pixels SP3. The sixth signal line TL6 may be electrically connected to a first electrode CE1 of the other third sub-pixel SP3 (for example, the 3-2^{th} sub-pixel SP3b) of the pair of third sub-pixels SP3.

The plurality of communication lines NL may be disposed at an area between the plurality of pixels PX. The plurality of communication lines NL may be disposed to extend in the row direction at the area between the plurality of pixels PX. The plurality of communication lines NL are disposed at an area between the plurality of second electrodes CE2 and may not overlap the plurality of second electrodes CE2. For example, the plurality of communication lines NL may be lines (or wirings) used for short-range communication such as near field communication (NFC). The plurality of communication lines NL may function as antennas. For example, the plurality of communication lines NL may be a plurality of connection lines, but is not limited thereto.

A bank BNK may be disposed at each of the plurality of sub-pixels. A plurality of banks BNK may be structures on which the plurality of light emitting devices ED are mounted. The plurality of banks BNK may guide positions of the plurality of light emitting devices ED in a transfer process of transferring the plurality of light emitting devices ED. In the transfer process of the plurality of light emitting devices ED, the plurality of light emitting devices ED may be transferred onto the plurality of banks BNK. An entire area of the light emitting device ED may overlap the bank BNK. For example, in a plan view, an entire size of the light emitting device ED may be smaller than the bank BNK. For example, the plurality of banks BNK may be bank patterns, structures, or protruding patterns, or the like, but is not limited thereto.

The bank BNK of the first sub-pixel SP1, the bank BNK of the second sub-pixel SP2, and the bank BNK of the third sub-pixel SP3 may be disposed to be spaced apart from each other along the row direction (or the second direction Y). The bank BNK of the first sub-pixel SP1, the bank BNK of the second sub-pixel SP2, and the bank BNK of the third sub-pixel SP3 may be configured to be separated from each other. Accordingly, in a process of transferring the light emitting device to the sub-pixel, the banks BNK of the first sub-pixel SP1, the second sub-pixel SP2, and the third sub-pixel SP3, to which different types of light emitting devices ED are transferred, may be easily identified, so that transfer defects in the transfer process of the light emitting devices may be prevented, minimized or at least reduced.

The bank BNK of the 1-1^{th} sub-pixel SP1a and the bank BNK of the 1-2^{th} sub-pixel SP1b may be connected to each other, or may be formed to be spaced apart or separated from each other. For example, considering the design of the transfer process requirements, or the like, the bank BNK of the 1-1^{th} sub-pixel SP1a and the bank BNK of the 1-2^{th} sub-pixel SP1b, in which the same type of light emitting device ED is disposed, may be connected to each other, or may be spaced apart or separated from each other. In addition, the bank BNK of the 2-1^{th} sub-pixel SP2a and the bank BNK of the 2-2^{th} sub-pixel SP2b may be connected to each other, or may be formed to be spaced apart or separated from each other. The bank BNK of the 3-1^{th} sub-pixel SP3a and the bank BNK of the 3-2^{th} sub-pixel SP3b may be connected to each other, or may be formed to be spaced apart or separated from each other. Therefore, the bank BNK of the pair of first sub-pixels SP1, the bank BNK of the pair of second sub-pixels SP2, and the bank BNK of the pair of third sub-pixels SP3 may be formed in various ways, but is not limited thereto.

The plurality of banks BNK may be made of an organic insulating material. The plurality of banks BNK may be composed of a single layer or multiple layers of the organic insulating material. For example, the plurality of banks BNK may be composed of a photo resist, a polyimide, or an acrylic-based material, or the like, but is not limited thereto.

The first electrode CE1 may be disposed at each of the plurality of sub-pixels. The first electrode CE1 may be disposed on the bank BNK while overlapping the bank BNK. The first electrode CE1 may be electrically connected to one of the plurality of signal lines TL. At least a portion of the first electrode CE1 may extend to an outside the bank BNK and be electrically connected to the signal line TL closest to the first electrode CE1. The portion of the first electrode CE1 may overlap the bank BNK, and the remaining portion of the first electrode CE1 may not overlap the bank BNK.

Aa portion of the first electrode CE1 of the 1-1^{th} sub-pixel SP1a may extend to one side of the 1-1^{th} sub-pixel SP1a and may be electrically connected to the first signal line TL1, and a portion of the first electrode CE1 of the 1-2^{th} sub-pixel SP1b may extend to the other side of the 1-2^{th} sub-pixel SP1b and may be electrically connected to the second signal line TL2. A portion of the first electrode CE1 of the 2-1^{th} sub-pixel SP2a may extend to one side of the 2-1^{th} sub-pixel SP2a and may be electrically connected to the third signal line TL3, and a portion of the first electrode CE1 of the 2-2^{th} sub-pixel SP2b may extend to the other side of the 2-2^{th} sub-pixel SP2b and may be electrically connected to the fourth signal line TL4. A portion of the first electrode CE1 of the 3-1^{th} sub-pixel SP3a may extend to one side of the 3-1^{th} sub-pixel SP3a and may be electrically connected to the fifth signal line TL5, and a portion of the first electrode CE1 of the 3-2^{th} sub-pixel SP3b may extend to the other side of the 3-2^{th} sub-pixel SP3b and may be electrically connected to the sixth signal line TL6.

The first electrode CE1 may be electrically connected to the anode electrode (or anode terminal) (134 illustrated in FIG. 9) of the light emitting device ED. The anode voltage from the pixel driving circuit (PD illustrated in FIG. 3) may be sequentially transmitted to the light emitting device ED through the signal line TL and the first electrode CE1. The pixel driving circuit (PD illustrated in FIG. 3) may apply the same voltage (or anode voltage) to the first electrode CE1 of each of the plurality of sub-pixels, but is not limited thereto. For example, the pixel driving circuit (PD illustrated in FIG. 3) may be configured to apply different voltages to the first electrode CE1 of each of the plurality of sub-pixels based on an image displayed on the corresponding sub-pixel. For example, different voltages may be applied to the first electrodes CE1 of each of the plurality of sub-pixels. Accordingly, the first electrode CE1 may be a pixel electrode, but is not limited thereto.

The first electrode CE1 may be composed of a conductive material. For example, the first electrode CE1 may be formed integrally with the plurality of signal lines TL. For example, the first electrode CE1 may be composed of the same conductive material as the plurality of signal lines TL, but is not limited thereto.

The plurality of light emitting devices ED may be disposed at the first electrode CE1 so as to overlap the bank BNK and the first electrode CE1. An entire area of the plurality of light emitting devices ED may overlap the bank BNK and the first electrode CE1. The plurality of light emitting devices ED may be in contact with the first electrode CE1 so as to overlap the bank BNK and the first electrode CE1.

The plurality of light emitting devices ED may disposed at the first electrode CE1 and may be electrically connected to the first electrode CE1. Therefore, the light emitting devices ED may emit light by receiving the anode voltage from the pixel driving circuit PD through the signal line TL and the first electrode CE1. For example, the light emitting device ED may emit light by the anode voltage applied to the first electrode CE1 and a cathode voltage applied to the second electrode CE2 in a display mode.

The plurality of light emitting devices ED may include a first light emitting device 130, a second light emitting device 140, and a third light emitting device 150.

The first light emitting device 130 may be disposed at the first sub-pixel SP1. The second light emitting device 140 may be disposed at the second sub-pixel SP2. The third light emitting device 150 may be disposed at the third sub-pixel SP3. For example, any one of the first light emitting device 130, the second light emitting device 140, and the third light emitting device 150 may be a red light emitting device, another light emitting device may be a green light emitting device, and the other light emitting device may be a blue light emitting device, but is not limited thereto. Accordingly, red light, green light, and blue light emitted from the plurality of light emitting devices ED may be combined to implement various colors of light including white. The types of the plurality of light emitting devices ED are exemplary, but is not limited thereto.

The first light emitting device 130 may include a 1-1^{th} light emitting device 130a disposed at a 1-1^{th} sub-pixel SP1a and a 1-2^{th} light emitting device 130b disposed at a 1-2^{th} sub-pixel SP1b. The second light emitting device 140 may include a 2-1^{th} light emitting device 140a disposed at a 2-1^{th} sub-pixel SP2a and a 2-2^{th} light emitting device 140b disposed at a 2-2^{th} sub-pixel SP2b. The third light emitting device 150 may include a 3-1^{th} light emitting device 150a disposed at a 3-1^{th} sub-pixel SP3a and a 3-2^{th} light emitting device 150b disposed at a 3-2^{th} sub-pixel SP3b.

A second electrode CE2 may be disposed at each of the plurality of sub-pixels. The second electrode CE2 may be disposed over the light emitting device ED. The second electrode CE2 may be electrically connected to the pixel driving circuit (PD illustrated in FIG. 3) through a plurality of contact electrodes CCE. The second electrode CE2 may be electrically connected to a cathode electrode (or cathode terminal) (135 illustrated in FIG. 9) of the light emitting device ED.

The second electrode CE2 may receive a cathode voltage (or a low potential power voltage) supplied from the pixel driving circuit (PD illustrated in FIG. 3) in the display mode. Accordingly, the second electrode CE2 may be used (or driven) as a common electrode electrically connected to the cathode electrode (or cathode terminal) (135 illustrated in FIG. 9) of the light emitting device ED.

The cathode voltage (or a common electrode voltage) applied to the second electrode CE2 of each of the plurality of sub-pixels may be the same. For example, the cathode voltage may be commonly applied to the second electrode CE2 of each of the plurality of sub-pixels and the cathode electrode (135 illustrated in FIG. 9) of the light emitting device ED. Accordingly, the second electrode CE2 may be a common electrode, a common electrode pattern, a common cathode electrode, a common cathode electrode pattern, a common divided electrode, or a common divided electrode pattern, but is not limited thereto.

The cathode voltage applied to the second electrode CE2 of each of the plurality of sub-pixels may be changed based on a reference voltage (Vref illustrated in FIG. 4). For example, the cathode voltage may be adjusted (or varied) according to screen brightness based on a user operation (or setting).

The second electrode CE2 according to one or more embodiments of the present disclosure may have a size corresponding to one row (or a horizontal line). For example, the second electrode CE2 may have a width corresponding to one row and may extend along the row direction (or the first direction X). For example, the second electrode CE2 may be commonly connected to the light emitting device ED in each of the plurality of pixels PX disposed along the row direction. For example, the second electrode CE2 may be commonly connected to a cathode electrode (135 illustrated in FIG. 9) of the light emitting device ED in each of 16 pixels PX disposed along the row direction, but is not limited thereto. For example, the second electrode CE2 may be commonly connected to the cathode electrode 135 illustrated in FIG. 9) of 96 light emitting devices ED disposed along the row direction, but is not limited thereto. For example, the second electrode CE2 may be commonly connected to the cathode electrode (135 illustrated in FIG. 9) of 192 light emitting devices ED in one row, but is not limited thereto.

Some of the second electrodes CE2 of each of the plurality of sub-pixels may be disposed to be spaced apart from or separated from each other. For example, the second electrodes CE2 connected to the pixels PX of a n^{th} row and the second electrodes CE2 connected to the pixels PX of a n+1^{th} row may be disposed to be spaced apart from or separated from each other. As one or more embodiments of the present disclosure, the plurality of second electrodes CE2 may be disposed to be spaced apart from each other with a plurality of communication lines NL extending in the row direction therebetween. Accordingly, the number of the plurality of sub-pixels may be greater than the number of the plurality of second electrodes CE2.

The second electrode CE2 may be configured to receive a touch driving signal supplied from the pixel driving circuit (PD illustrated in FIG. 3) in the first touch mode or the second touch mode. Accordingly, the second electrode CE2 may be used (or driven) as a touch electrode (or a contact touch electrode or a non-contact touch electrode) TE for touch sensing in the first touch mode or the second touch mode.

The plurality of second electrodes CE2 disposed in the display area may be used (or driven) as a touch driving electrode that receive a touch driving signal, or as a touch sensing electrode that sense a user's touch, depending on their positions. For example, the plurality of second electrodes CE2 disposed (or configured) on the first touch electrode part of the display area may be used (or driven) as a touch driving electrode or a touch driving/sensing electrode in the first touch mode, and may be used (or driven) as a hover touch driving electrode in the second touch mode. For example, the plurality of second electrodes CE2 disposed (or configured) on the second touch electrode part of the display area may be used (or driven) as a hover touch sensing electrode in the second touch mode, but are not limited thereto. For example, the plurality of second electrodes CE2 disposed (or configured) on the second touch electrode part of the display area may be used (or driven) as a touch guard electrode or a touch shield electrode that receives an auxiliary driving signal in the first touch mode.

The plurality of second electrodes CE2 may be composed of a transparent conductive material, but is not limited thereto. The plurality of second electrodes CE2 may be composed of a transparent conductive material so that light emitted from the light emitting device ED may be directed toward an upper portion of the second electrodes CE2.

The plurality of contact electrodes CCE may be disposed on the substrate 110. For example, the plurality of contact electrodes CCE may be disposed to be spaced apart from the plurality of banks BNK and the plurality of signal lines TL. Each of the plurality of second electrodes CE2 may overlap at least one contact electrode CCE. For example, one second electrode CE2 may overlap the plurality of contact electrodes CCE.

The plurality of contact electrodes CCE may be electrically connected to the plurality of second electrodes CE2. The plurality of contact electrodes CCE may be disposed between the substrate 110 and the plurality of second electrodes CE2, and may be configured to transmit the cathode voltage or the touch driving signal supplied from the pixel driving circuit (PD illustrated in FIG. 3) through a low-potential power line to the second electrodes CE2.

When the light emitting device ED is configured as a micro light emitting diode chip, a plurality of micro light emitting diode chips may be formed on a wafer, and the micro light emitting diode chips may be transferred to a substrate 110 to manufacture a display panel 100. In the process of transferring a plurality of light emitting devices ED having a micro size (or fine size) from the wafer to the substrate 110, various defects may occur. For example, in some sub-pixels, a defect may occur in which the light emitting device ED is not transferred, and in other sub-pixels, a defect may occur in which the light emitting device ED is transferred out of its proper position due to an alignment error. In addition, the transfer process may proceed normally, but the transferred light emitting device ED itself may be defective. Therefore, in consideration of defects that may occur during the transfer process of the plurality of light emitting devices ED, a plurality of light emitting devices ED of the same type may be transferred to one sub-pixel. A lighting test of the plurality of light emitting devices ED may be performed, and only one light emitting device ED that is finally determined to be normal may be used.

The 1-1^{th} light emitting device 130a and the 1-2^{th} light emitting device 130b may be transferred together to one pixel PX, and may be inspected for defects therein. As one or more embodiments of the present disclosure, when the 1-1^{th} light emitting device 130a and the 1-2^{th} light emitting device 130b are determined to be normal, only the 1-1^{th} light emitting device 130a may be used, and the 1-2^{th} light emitting device 130b may be unused. In one or more other embodiments of the present disclosure, if only the 1-2^{th} light emitting device 130b among the 1-1^{th} light emitting device 130a and the 1-2^{th} light emitting device 130b is determined to be normal, the 1-1^{th} light emitting device 130a is not used, and only the 1-2^{th} light emitting device 130b may be used. Therefore, even if multiple light emitting devices EDs of the same type are transferred to one pixel PX, only one light emitting device ED may ultimately be used.

Any one of a pair of light emitting devices ED may be a main (or a primary) light emitting device ED, and the other light emitting device ED may be a redundancy light emitting device ED. The redundancy light emitting device ED may be a spare light emitting device ED that is transferred in preparation for a failure of the main light emitting device ED. When the main light emitting device ED fails, the redundancy light emitting device ED may be used as a replacement for the main light emitting device ED. Therefore, by transferring the main light emitting device ED and the redundancy light emitting device ED together to one pixel PX, it is possible to minimize or at least reduce a deterioration in display quality due to a failure of the main light emitting device ED and the redundancy light emitting device ED. For example, the 1-1^{th} light emitting device 130a, the 2-1^{th} light emitting device 140a, and the 3-1^{th} light emitting device 150a transferred to the one pixel PX may be used as the main light emitting device ED, and the 1-2^{th} light emitting device 130b, the 2-2^{th} light emitting device 140b, and the 3-2^{th} light emitting device 150b may be used as the redundancy light emitting device ED.

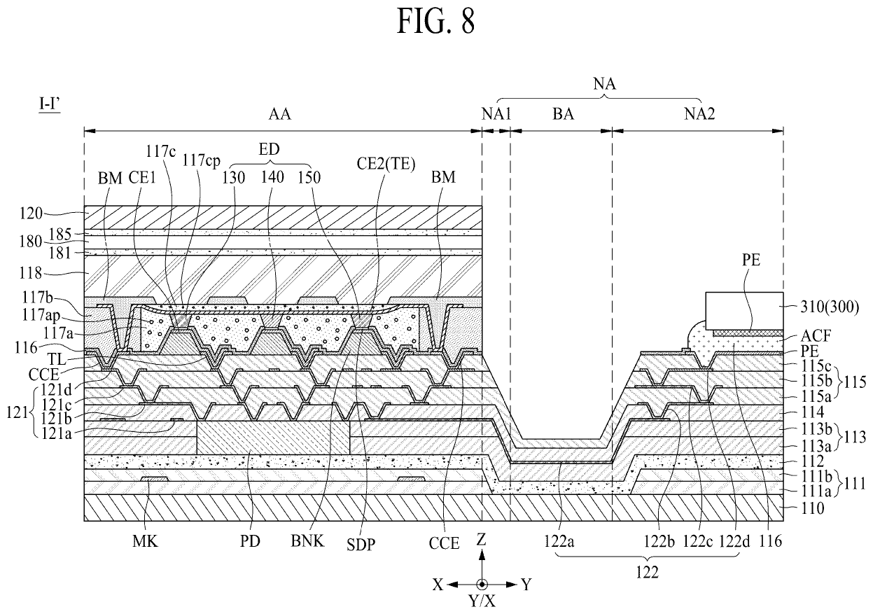

FIG. 8 is a cross-sectional view taken along line I-I′ illustrated in FIG. 2 or FIG. 3. FIG. 9 is a cross-sectional view of a first light emitting device according to one or more embodiments of the present disclosure. For example, FIG. 8 is a cross-sectional view of a display area AA, a first non-display area NA, a bending area BA, and a second non-display area NA2 taken along line I-I′ illustrated in FIG. 2 or FIG. 3, and FIG. 9 is a cross-sectional view of a portion of the display area AA.

Referring to FIG. 8, a buffer layer 111 may be disposed at the remaining area of the substrate 110 excluding the bending area BA. The buffer layer 111 may include a first buffer layer 111a and a second buffer layer 111b.

The first buffer layer 111a and the second buffer layer 111b may be disposed at the display area AA, the first non-display area NA1, and the second non-display area NA2. The first buffer layer 111a and the second buffer layer 111b may reduce penetration of moisture or impurities through the substrate 110. The first buffer layer 111a and the second buffer layer 111b may be composed of an inorganic insulating material.

A portion of the first buffer layer 111a and the second buffer layer 111b on the bending area BA may be removed. An upper surface of the substrate 110 located at the bending area BA may be exposed without being covered by the first buffer layer 111a and the second buffer layer 111b. Since the portion of the first buffer layer 111a and the second buffer layer 111b made of an inorganic insulating material is removed at the bending area BA, cracks generated at the first buffer layer 111a and the second buffer layer 111b may be prevented, minimized or at least reduced when the bending area BA is bent.

A plurality of alignment keys MK may be disposed between the first buffer layer 111a and the second buffer layer 111b. The plurality of alignment keys MK may be configured to identify (or align) a position of pixel driving circuit PD during a manufacturing process of the display panel 100. For example, the plurality of alignment keys MK may be configured to align the position of pixel driving circuit PD transferred onto an adhesive layer 112. For example, the plurality of alignment keys MK may be omitted, but is not limited thereto.

The adhesive layer 112 may be disposed on the second buffer layer 111b. The adhesive layer 112 may be disposed at the display area AA, the first non-display area NA1, the bending area BA, and the second non-display area NA2. For example, in the non-display areas NA1 and NA2 including the bending area BA, at least a portion of the adhesive layer 112 may be removed.

In the display area AA, the pixel driving circuit PD may be disposed on the adhesive layer 112. The pixel driving circuit PD may be supported by the buffer layer 111. When the pixel driving circuit PD is implemented as a driving driver (or a driving driver integrated circuit or a driving driver chip), the driving driver may be mounted on the adhesive layer 112 by a transfer process, but is not limited thereto.

A protective layer 113 may be disposed on the adhesive layer 112 and the pixel driving circuit PD. The protective layer 113 may include a first protective layer 113a and a second protective layer 113b. For example, the first protective layer 113a and the second protective layer 113b may be disposed on the adhesive layer 112 and the pixel driving circuit PD. The first protective layer 113a and the second protective layer 113b may be disposed to surround a side surface (or lateral surface) of the pixel driving circuit PD, but is not limited thereto. For example, the second protective layer 113b may be disposed to cover at least a portion of an upper surface of the pixel driving circuit PD. For example, at least one of the first protective layer 113a and the second protective layer 113b disposed on the bending area BA may be omitted. For example, the first protective layer 113a may be entirely disposed at the display area AA and the non-display area NA, and the second protective layer 113b may be partially disposed at the display area AA, the first non-display area NA1, and the second non-display area NA2, and may not be disposed at the bending area BA. For example, the second protective layer 113b (or a portion of the first protective layer 113a) at the bending area BA may be removed, but is not limited thereto.

The first protective layer 113a and the second protective layer 113b may be composed of an organic insulating material, but is not limited thereto. For example, the first protective layer 113a and the second protective layer 113b may be an overcoating layer, an insulating layer, or an organic insulating layer, but is not limited thereto.

A wiring layer (or line layer or pixel wiring layer) may be disposed on the protective layer 113. For example, the wiring layer may be configured to surround or cover the pixel driving circuit PD. The wiring layer may include a plurality of first connection lines 121.

The plurality of first connection lines 121 may be disposed on the protective layer 113. For example, the plurality of first connection lines 121 may be disposed on the second protective layer 113b at the display area AA. The plurality of first connection lines 121 may be lines (or intermediate lines or jumping lines) configured to electrically connect the pixel driving circuit PD to other components and/or lines in different layers. For example, the pixel driving circuit PD may be electrically connected to a plurality of signal lines TL and a plurality of contact electrodes CCE, or the like through the plurality of first connection lines 121.

The plurality of first connection lines 121 may include a 1-1^{th} connection line 121a, a 1-2^{th} connection line 121b, a 1-3^{th} connection line 121c, and a 1-4^{th} connection line 121d, but is not limited thereto. For example, the plurality of 1-1^{th} connection lines 121a may be disposed on the second protective layer 113b. The plurality of 1-1^{th} connection lines 121a may be configured to be electrically connected to the pixel driving circuit PD. The plurality of 1-1^{th} connection lines 121a may be configured to transmit a voltage output from the pixel driving circuit PD to the first electrode CE1 or the second electrode CE2.

A third protective layer 114 may be disposed on the second protective layer 113b. The third protective layer 114 may be entirely disposed at the display area AA and the non-display area NA. In the bending area BA, the third protective layer 114 may cover or enclose side surfaces (or lateral surfaces) of the second protective layer 113b and the upper surface of the first protective layer 113a. The third protective layer 114 may be composed of an organic insulating material. For example, the first protective layer 113a, the second protective layer 113b, and the third protective layer 114 may be composed of the same material, but is not limited thereto.

The plurality of 1-2^{th} connection lines 121b may be disposed on the third protective layer 114. The plurality of 1-2^{th} connection lines 121b may be connected to the pixel driving circuit PD through the 1-1^{th} connection line 121a or may be directly connected to the pixel driving circuit PD. For example, a portion of the 1-2^{th} connection line 121b may be directly connected to the pixel driving circuit PD through a contact hole of the third protective layer 114. Another portion of the 1-2^{th} connection line 121b may be electrically connected to the 1-1^{th} connection line 121a through a contact hole of the third protective layer 114. However, embodiments of the present disclosure are not limited thereto. As one or more embodiments of the present disclosure, a voltage output from the pixel driving circuit PD may be transmitted to the first electrode CE1 or the second electrode CE2 through the plurality of 1-2^{th} connection lines 121b and other connection lines.

The display apparatus 1000 according to one or more embodiments of the present disclosure may further include an insulating layer 115 in the wiring layer. The insulating layer 115 may be configured to electrically insulate the plurality of first connection lines 121 and cover the plurality of first connection lines 121. For example, the insulating layer 115 may include a plurality of insulating layers 115a, 115b, and 115c or may include first to third insulating layers 115a, 115b, and 115c.

The first insulating layer 115a may be disposed on the plurality of 1-2^{th} connection lines 121b. The first insulating layer 115a may be entirely disposed at the display area AA and the non-display area NA, but is not limited thereto. The first insulating layer 115a may be composed of an organic insulating material, but is not limited thereto.

The plurality of 1-3^{th} connection lines 121c may be disposed on the first insulating layer 115a. The plurality of 1-3^{th} connection lines 121c may be electrically connected to the plurality of 1-2^{th} connection lines 121b. For example, the 1-3^{th} connection line 121c may be electrically connected to the 1-2^{th} connection line 121b through a contact hole of the first insulating layer 115a.

A second insulating layer 115b may be disposed on the plurality of 1-3^{th} connection lines 121c. The second insulating layer 115b may be disposed at the remaining area except for the bending area BA, but is not limited thereto. The second insulating layer 115b may be disposed at the display area AA, the first non-display area NA1, and the second non-display area NA2, but is not limited thereto. For example, at least a portion of the second insulating layer 115b disposed at the bending area BA may be removed. The second insulating layer 115b may be composed of an organic insulating material, but is not limited thereto.

The plurality of 1-4^{th} connection lines 121d may be disposed on the second insulating layer 115b. The plurality of 1-4^{th} connection lines 121d may be electrically connected to the plurality of 1-3^{th} connection lines 121c. For example, the 1-4^{th} connection line 121d may be electrically connected to the 1-3^{th} connection line 121c through a contact hole of the second insulating layer 115b.

The 1-4^{th} connection line 121d may be connected to the contact electrode CCE through a contact hole of the third insulating layer 115c, and accordingly, the contact electrode CCE and the pixel driving circuit PD may be electrically connected by the first connection line 121. For example, the contact electrode CCE connected to the second electrode CE2 may be electrically connected to the pixel driving circuit PD through the 1-4^{th} connection line 121d, the 1-3^{th} connection line 121c, the 1-2^{th} connection line 121b, and the 1-1^{th} connection line 121a.

The 1-4^{th} connection line 121d may be directly connected to the signal line TL through a contact hole provided at the third insulating layer 115c, or may be electrically connected to the signal line TL through another additional line or electrode, and accordingly, the signal line TL and the pixel driving circuit PD may be electrically connected by the first connection line 121.

A plurality of second connection lines 122 may be disposed on the protective layer 113 in the non-display area NA. For example, the plurality of second connection lines 122 may be disposed on the second protective layer 113b in the non-display area NA. The plurality of second connection lines 122 may be lines for transmitting signals transmitted from a flexible circuit board (310 illustrated in FIG. 2) and a printed circuit board (330 illustrated in FIG. 2) through a pad portion (PAD illustrated in FIG. 2) to the pixel driving circuit PD in the display area AA.

The plurality of second connection lines 122 may be electrically connected to a plurality of pad electrodes PE and may receive signals from the flexible circuit board (310 illustrated in FIG. 2) and the printed circuit board (330 illustrated in FIG. 2).

The plurality of second connection lines 122 may be configured to extend from the pad portion (PAD illustrated in FIG. 2) toward the display area AA and transmit the signals to the lines of the display area AA. In this case, the plurality of second connection lines 122 may function as link lines (LL illustrated in FIG. 3).

The plurality of second connection lines 122 may include a 2-1^{th} connection line 122a, a 2-2^{th} connection line 122b, a 2-3^{th} connection line 122c, and a 2-4^{th} connection line 122d.

A plurality of 2-1^{th} connection lines 122a may be disposed on the protective layer 113. For example, the plurality of 2-1^{th} connection lines 122a may be disposed on the second protective layer 113b. The plurality of 2-1^{th} connection lines 122a may extend from the second non-display area NA2 to the bending area BA and the first non-display area NA1. The plurality of 2-1^{th} connection lines 122a may be configured to transmit the signals transmitted from the flexible circuit board (310 illustrated in FIG. 2) and the printed circuit board (330 illustrated in FIG. 2) through the pad portion (PAD illustrated in FIG. 2) to the pixel driving circuit PD of the display area AA.

A plurality of 2-1^{th} connection lines 122a may be electrically connected to the pad electrode PE and the pixel driving circuit PD, respectively. For example, the 2-1^{th} connection line 122a may extend to the display area AA and may be directly connected to the pixel driving circuit PD within the display area AA, or may be electrically connected to the pixel driving circuit PD through other additional lines or electrodes. In addition, the 2-1^{th} connection line 122a may be electrically connected to the pad electrode PE within the second non-display area NA2 through the 2-2^{th} connection line 122b, the 2-3^{th} connection line 122c, and the 2-4^{th} connection line 122d. Therefore, the pixel driving circuit PD and the pad electrode PE may be electrically connected by the second connection lines 122.

A plurality of 2-2^{th} connection lines 122b may be disposed on the third protective layer 114. The plurality of 2-2^{th} connection lines 122b may be disposed at the second non-display area NA2. The 2-2^{th} connection line 122b may be electrically connected to the 2-1^{th} connection line 122a through the contact hole of the third protective layer 114. Accordingly, signals from the flexible circuit board (310 illustrated in FIG. 2) and the printed circuit board (330 illustrated in FIG. 2) may be transmitted to the 2-1^{th} connection line 122a through the 2-2^{th} connection line 122b.

The 2-3^{th} connection line 122c may be disposed on the first insulating layer 115a. The 2-3^{th} connection line 122c may be disposed at the second non-display area NA2. The 2-3^{th} connection line 122c may be electrically connected to the 2-2^{th} connection line 122b through the contact hole of the first insulating layer 115a. Therefore, signals from the flexible circuit board (310 illustrated in FIG. 2) and the printed circuit board (330 illustrated in FIG. 2) may be transmitted to the 2-1^{th} connection line 122a through the 2-3^{th} connection line 122c and the 2-2^{th} connection line 122b.

The 2-4^{th} connection line 122d may be disposed on the second insulating layer 115b. The 2-4^{th} connection line 122d may be disposed at the second non-display area NA2. The 2-4^{th} connection line 122d may be electrically connected to the 2-3^{th} connection line 122c through the contact hole of the second insulating layer 115b. The 2-4^{th} connection line 122d may be electrically connected to the pad electrode PE through the contact hole of the third insulating layer 115c.

Signals from the flexible circuit board (310 illustrated in FIG. 2) and the printed circuit board (330 illustrated in FIG. 2) may be transmitted to the 2-1^{th} connection line 122a through the 2-4^{th} connection line 122d, the 2-3^{th} connection line 122c, and the 2-2^{th} connection line 122b. For example, the 2-2^{th} connection line 122a may extend to the display area AA through the bending area BA, and may be electrically connected to the pixel driving circuit PD in the display area AA. Therefore, the pad electrode PE provided in the second non-display area NA2 may be electrically connected to the pixel driving circuit PD provided in the display area AA through the 2-4^{th} connection line 122d, the 2-3^{th} connection line 122c, the 2-2^{th} connection line 122b, and the 2-1^{th} connection line 122a provided in the bending area BA.

The plurality of first connection lines 121 and the plurality of second connection lines 122 may be formed of any one of a conductive material having excellent ductility characteristics or various conductive materials used in the display area AA.

The third insulating layer 115c may be disposed on the plurality of first connection lines 121 and the plurality of second connection lines 122. The third insulating layer 115c may be disposed at the remaining area except for the bending area BA, but is not limited thereto. The third insulating layer 115c may be disposed at the display area AA, the first non-display area NA1, and the second non-display area NA2. At least a portion of the third insulating layer 115c in the bending area BA may be removed. The third insulating layer 115c may be composed of an organic insulating material, but is not limited thereto.

A plurality of banks BNK may be disposed on the third insulating layer 115c in the display area AA. The plurality of banks BNK may be disposed to overlap each of the plurality of sub-pixels. The plurality of banks BNK may not be disposed in the first non-display area NA1, the second non-display area NA2, and the bending area BA. One or more light emitting devices ED of the same type may be disposed on each of the plurality of banks BNK.

A plurality of signal lines TL may be disposed on the third insulating layer 115c in the display area AA. The plurality of signal lines TL may be disposed at an area between the plurality of banks BNK. For example, the plurality of signal lines TL may be disposed adjacent to any one of the plurality of banks BNK. Each of the plurality of signal lines TL may be electrically connected to the first connection line 121, for example, the 1-4^{th} connection line 121d.

A plurality of contact electrodes CCE may be disposed on the third insulating layer 115c in the display area AA. The plurality of contact electrodes CCE may supply a cathode voltage from the pixel driving circuit PD to the second electrode CE2. Each of the plurality of contact electrodes CCE may be electrically connected to the first connection line 121, for example, the 1-4^{th} connection line 121d.

The first electrode CE1 may be disposed on the bank BNK. For example, the first electrode CE1 may be disposed to extend from adjacent signal line TL toward an upper portion of the bank BNK. The first electrode CE1 may be disposed on an upper surface of the bank BNK and a side surface of the bank BNK. For example, the first electrode CE1 may be disposed to extend from the signal line TL on the third insulating layer 115c to the side surface of the bank BNK and the upper surface of the bank BNK. The first electrode CE1 may be a contact electrode. The first electrode CE1 may be formed integrally with the signal line TL.

Referring to FIG. 9, the first electrode CE1 may be composed of a plurality of conductive layers. For example, the first electrode CE1 may include a first conductive layer CE1a, a second conductive layer CE1b, a third conductive layer CE1c, and a fourth conductive layer CE1d, but is not limited thereto.

The first conductive layer CE1a may be disposed on the bank BNK. The second conductive layer CE1b may be disposed on the first conductive layer CE1a. The third conductive layer CE1c may be disposed on the second conductive layer CE1b. The fourth conductive layer CE1d may be disposed on the third conductive layer CE1c.

Some of the conductive layers having high reflection efficiency, among the plurality of conductive layers configuring the first electrode CE1, may be configured as an alignment key and/or a reflective plate (or reflector) for aligning the light emitting device ED. For example, the second conductive layer CE1b among the plurality of conductive layers configuring the first electrode CE1 may include a reflective material. For example, the second conductive layer CE1b may include aluminum (Al), but is not limited thereto. Accordingly, the second conductive layer CE1b may be configured as the reflective plate. In addition, due to the high reflection efficiency of the second conductive layer CE1b, it may be easy to identify in a manufacturing process, and thus, a position or a transfer position of the light emitting device ED may be aligned based on the second conductive layer CE1b.

In order to configure the second conductive layer CE1b as the reflective plate, the third conductive layer CE1c and the fourth conductive layer CE1d covering the second conductive layer CE1b may be partially removed or etched. For example, a portion of the third conductive layer CE1c and the fourth conductive layer CE1d disposed on the bank BNK may be removed or etched, thereby exposing an upper surface of the second conductive layer CE1b. For example, a center portion and a border portion (or an edge portion) of the third conductive layer CE1c and the fourth conductive layer CE1d, where the solder pattern SDP is disposed, may not be removed, and the remaining portions other than these may be removed. For example, the border portion (or edge portion) and the center portion of each of the third conductive layer CE1c which is made of titanium (Ti) and the fourth conductive layer CE1d which is made of indium tin oxide may not be removed or etched. Accordingly, corrosion of other conductive layers configuring the first electrode CE1 may be prevented, minimized or at least reduced by an etchant (for example, a TMAH (tetramethyl ammonium hydroxide) solution) used in a mask process (or patterning process) of the first electrode CE1.

The first conductive layer CE1a and the third conductive layer CE1c may include titanium (Ti) or molybdenum (Mo). The second conductive layer CE1b may include aluminum (Al). The fourth conductive layer CE1d may include a transparent conductive oxide layer, such as indium tin oxide (ITO) or indium zinc oxide (IZO), which has good adhesion to the solder pattern SDP and has corrosion resistance and acid resistance. However, embodiments of the present disclosure are not limited thereto.

The first conductive layer CE1a, the second conductive layer CE1b, the third conductive layer CE1c, and the fourth conductive layer CE1d may be sequentially deposited and then patterned by a photolithography process and an etching process, but is not limited thereto.

As can be seen in FIGS. 8 and 9, the signal line TL, the contact electrode CCE, and the pad electrode PE disposed at the same layer as the first electrode CE1 may be configured with a multilayer structure of a conductive material, but is not limited thereto.

The solder pattern SDP may be disposed on the first electrode CE1 in each of the plurality of sub-pixels. The solder pattern SDP may bond the light emitting device ED to the first electrode CE1. The first electrode CE1 and the light emitting device ED may be electrically connected through eutectic bonding using the solder pattern SDP, but is not limited thereto. For example, when the solder pattern SDP is made of indium (In) and the anode electrode 134 of the light emitting device ED is made of gold (Au), the solder pattern SDP and the anode electrode 134 may be bonded by applying heat and pressure in a transfer process of the light emitting device ED. The light emitting device ED may be bonded to the solder pattern SDP and the first electrode CE1 through eutectic bonding without a separate adhesive. For example, the solder pattern SDP may be composed of indium (In), tin (Sn), or an alloy thereof, but is not limited thereto. For example, the solder pattern SDP may be a contact pattern, a bonding pad, or a joining pad, or the like, but is not limited thereto.

A passivation layer 116 may be disposed on the wiring layer. For example, the passivation layer 116 may be configured to cover the wiring layer in the display area AA. For example, the passivation layer 116 may be disposed on the plurality of signal lines TL, the plurality of first electrodes CE1, the plurality of contact electrodes CCE, and the third insulating layer 115c. For example, the passivation layer 116 may be disposed at the display area AA, the first non-display area NA1, and the second non-display area NA2. At least a portion of the passivation layer 116 disposed at the bending area BA may be removed. A portion of the passivation layer 116 covering the plurality of pad electrodes PE in the second non-display area NA2 may be removed. A portion of the passivation layer 116 covering the plurality of contact electrodes CCE in the display area AA may be removed. The passivation layer 116 covering the solder pattern SDP in the display area AA may be removed. The passivation layer 116 may cover the first electrode CE1. The passivation layer 116 may cover a portion of the upper surface of the exposed second conductive layer CE1b.

The passivation layer 116 is disposed to expose at least a portion of the plurality of pad electrodes PE, the plurality of contact electrodes CCE, and the solder pattern SDP while covering the remaining area, so as to reduce the penetration of moisture or impurities into the light emitting device ED. For example, the passivation layer 116 may be a protective layer, an insulating layer, or an inorganic insulating layer, or the like, but is not limited thereto. For example, the passivation layer 116 may include a hole exposing the solder pattern SDP and a hole exposing the contact electrode CCE.

In each of the plurality of sub-pixels, the light emitting device ED may be disposed on the solder pattern SDP. A first light emitting device 130 may be disposed in a first sub-pixel SP1. A second light emitting device 140 may be disposed in a second sub-pixel SP2. A third light emitting device 150 may be disposed in a third sub-pixel SP3.

The light emitting device ED may be formed on a silicon wafer by a method such as metal organic chemical vapor deposition, chemical vapor deposition, plasma-enhanced chemical vapor deposition, molecular beam epitaxy, hydride vapor phase epitaxy, or sputtering, or the like, but is not limited thereto.

Referring to FIG. 9, the first light emitting device 130 may include an anode electrode 134, a first semiconductor layer 131, an active layer 132, a second semiconductor layer 133, a cathode electrode 135, and an encapsulation film 136, but is not limited thereto. For example, the encapsulation film 136 may not be included in the first light emitting device 130.

The first semiconductor layer 131 may be disposed on a solder pattern SDP. The second semiconductor layer 133 may be disposed on the first semiconductor layer 131.

One of the first semiconductor layer 131 and the second semiconductor layer 133 may be implemented as a compound semiconductor of a group III-V or a group II-VI, or the like, and may be doped with an impurity (or dopant). For example, one of the first semiconductor layer 131 and the second semiconductor layer 133 may be a semiconductor layer doped with an n-type impurity, and the other may be a semiconductor layer doped with a p-type impurity, but is not limited thereto.

The first semiconductor layer 131 and the second semiconductor layer 133 may be a nitride semiconductor including the n-type impurity and a nitride semiconductor including the p-type impurity, respectively, but is not limited thereto. For example, the first semiconductor layer 131 may be a nitride semiconductor including the p-type impurity, and the second semiconductor layer 133 may be a nitride semiconductor including the n-type impurity, but is not limited thereto.

The active layer 132 may be disposed (or interposed) between the first semiconductor layer 131 and the second semiconductor layer 133. The active layer 132 may receive holes and electrons from the first semiconductor layer 131 and the second semiconductor layer 133 to emit light. For example, the active layer 132 may be configured as one of a single well structure, a multi-well structure, a single quantum well structure, a multi-quantum well structure, a quantum dot structure, and a quantum line structure, but is not limited thereto. For example, the active layer 132 may be configured as indium gallium nitride (InGaN) or gallium nitride (GaN), or the like, but is not limited thereto.

The active layer 132 may include a multi-quantum well structure having a well layer and a barrier layer having a higher band gap than the well layer. For example, the active layer 132 may include an indium gallium nitride (InGaN) layer as a well layer and an aluminum gallium nitride (AlGaN) layer as a barrier layer, but is not limited thereto.

The anode electrode 134 may be disposed (or interposed) between the first semiconductor layer 131 and the solder pattern SDP. For example, the anode electrode 134 may be configured to electrically connect the first semiconductor layer 131 and the first electrode CE1. The anode voltage output from the pixel driving circuit PD may be applied to the first semiconductor layer 131 through the signal line TL, the first electrode CE1, and the anode electrode 134. For example, the anode electrode 134 may be composed of a conductive material capable of eutectic bonding with the solder pattern SDP, but is not limited thereto.

The cathode electrode 135 may be disposed on the second semiconductor layer 133. For example, the cathode electrode 135 may be configured to electrically connect the second semiconductor layer 133 and the second electrode CE2. A cathode voltage output from the pixel driving circuit PD may be applied to the second semiconductor layer 133 through the contact electrode CCE, the second electrode CE2, and the cathode electrode 135. The cathode electrode 135 may be composed of a transparent conductive material so that light emitted from the light emitting device ED may be directed toward an upper portion of the light emitting device ED, but is not limited thereto.

The encapsulation film 136 may be disposed on at least a portion of the first semiconductor layer 131, the active layer 132, the second semiconductor layer 133, the anode electrode 134, and the cathode electrode 135. For example, the encapsulation film 136 may surround at least a portion of the first semiconductor layer 131, the active layer 132, the second semiconductor layer 133, the anode electrode 134, and the cathode electrode 135.

The encapsulation film 136 may protect the first semiconductor layer 131, the active layer 132, and the second semiconductor layer 133. For example, the encapsulation film 136 may be disposed on side surfaces (or lateral surface) of the first semiconductor layer 131, side surfaces (or lateral surface) of the active layer 132, and side surfaces (or lateral surface) of the second semiconductor layer 133.

The encapsulation film 136 may be disposed on at least a portion of the anode electrode 134 and the cathode electrode 135 (for example, an edge portion (or a periphery portion or one side) of the anode electrode 134 and an edge portion (or a periphery portion or one side) of the cathode electrode 135). At least a portion of the anode electrode 134 that is not covered by the encapsulation film 136 may be exposed so that the anode electrode 134 and the solder pattern SDP may be connected. For example, at least a portion of the cathode electrode 135 that is not covered by the encapsulation film 136 may be exposed so that the cathode electrode 135 and the second electrode CE2 may be connected. For example, the encapsulation film 136 may be made of an insulating material such as silicon nitride (SiNx) or silicon oxide (SiOx), but is not limited thereto.

The encapsulation film 136 may have a structure in which a reflective material is dispersed in a resin layer, but is not limited thereto. For example, the encapsulation film 136 may be manufactured as a reflector of various structures, but is not limited thereto. Light emitted from the active layer 132 may be reflected upward by the encapsulation film 136, thereby improving light extraction efficiency. For example, the encapsulation film 136 may be a reflective layer, but is not limited thereto.

The light emitting device ED has been described as having a vertical structure, but is not limited thereto. For example, the light emitting device ED may have a lateral structure or a flip chip structure.

Although the first light emitting device 130 has been described with reference to FIG. 9, the second light emitting device 140 and the third light emitting device 150 may have substantially the same structure as the first light emitting device 130. For example, the second light emitting device 140 and the third light emitting device 150 include substantially the same configuration as the first semiconductor layer 131, the active layer 132, the second semiconductor layer 133, the anode electrode 134, the cathode electrode 135, and the encapsulation film 136 of the first light emitting device 130, and thus, their repetitive descriptions are omitted.

As can be seen in FIGS. 8 and 9, the display apparatus 1000 according to one or more embodiments of the present disclosure may further include an optical layer (or light diffusion layer) 117a, 117b, and 117c.

The optical layers 117a, 117b, and 117c may be configured to surround a plurality of light emitting devices ED in the display area AA. For example, the optical layers 117a, 117b, and 117c may be configured to cover the plurality of light emitting devices ED in the display area AA. For example, the optical layers 117a and 117b may be configured over the insulating layer 115 to surround side surfaces of each of the plurality of light emitting devices ED and the side surfaces of each of the plurality of banks BNK.

A first optical layer 117a may be disposed to surround the plurality of light emitting devices ED in the display area AA. For example, the first optical layer 117a may be disposed to cover side surfaces of the plurality of light emitting devices ED and side surfaces of the plurality of banks BNK in areas of the plurality of sub-pixels. For example, the first optical layer 117a may cover a portion of the passivation layer 116. For example, the first optical layer 117a may cover the second electrode CE2, the portion of the passivation layer 116, and between the plurality of light emitting devices ED. The first optical layer 117a may be disposed or cover between the plurality of light emitting devices ED included in one pixel PX and between the plurality of banks BNK. For example, the first optical layer 117a may extend along a row direction of the display area AA, and the plurality of first optical layers 117a may be spaced apart along a column direction (or the second direction Y) of the display area AA. For example, the first optical layer 117a may be disposed to surround side portions of each of the plurality of light emitting devices ED and the plurality of banks BNK between the insulating layer 115 and the second electrode CE2. For example, the first optical layer 117a may be disposed to surround side portions of each of the light emitting devices ED and the banks BNK between the passivation layer 116 and the second electrode CE2, but is not limited thereto. For example, the first optical layer 117a may be a diffusion layer or a sidewall diffusion layer, but is not limited thereto.

The first optical layer 117a may include an organic insulating material having fine particles 117ap dispersed therein, but is not limited thereto. For example, the first optical layer 117a may be composed of siloxane having fine particles 117ap, such as titanium dioxide (TiO particles, dispersed therein, but is not limited thereto. Light from a plurality of light emitting devices ED may be scattered by the fine particles 117ap dispersed in the first optical layer 117a and emitted to an outside of the display panel 100. Accordingly, the first optical layer 117a may improve the extraction efficiency of light emitted from the plurality of light emitting devices ED.

The first optical layer 117a may be disposed at each of the plurality of pixels PX, or may be disposed together at some of the pixels PX which are disposed in the same row of the display area AA, but is not limited thereto. For example, the first optical layer 117a may be disposed at each of the plurality of pixels PX, or one first optical layer 117a may be disposed to share the plurality of pixels PX. As one or more other embodiments of the present disclosure, each of the plurality of sub-pixels may separately include the first optical layer 117a, but is not limited thereto.

A second optical layer 117b may be disposed on the passivation layer 116 in the display area AA. For example, the second optical layer 117b may be disposed to surround side portions of the first optical layer 117a. For example, the second optical layer 117b may be in contact with side surfaces of the first optical layer 117a. For example, the second optical layer 117b may be disposed at an area (or a non-emitting area) between a plurality of pixels PX, but is not limited thereto. For example, the second optical layer 117b may be a diffusion layer, a diffusion layer window, or a window diffusion layer, or the like, but is not limited thereto.

The second optical layer 117b may be composed of an organic insulating material, but is not limited thereto. The second optical layer 117b may be composed of the same material as the first optical layer 117a, but is not limited thereto. For example, the first optical layer 117a may include fine particles, and the second optical layer 117b may not include the fine particles. For example, the second optical layer 117b may be composed of siloxane, but is not limited thereto.

A thickness of the first optical layer 117a may be smaller than a thickness of the second optical layer 117b, but is not limited thereto. For example, an upper surface of the second optical layer 117b may be formed as a flat surface, and an upper surface of the first optical layer 117a may be formed as a concave curved surface. Accordingly, when viewed in a plan view, an area where the first optical layer 117a is disposed may include a concave portion which is recessed inwardly more than the upper surface of the second optical layer 117b.

The second electrode CE2 may be disposed on the first optical layer 117a and the second optical layer 117b. For example, the second electrode CE2 may be electrically connected to the plurality of contact electrodes CCE through a contact hole of the second optical layer 117b. For example, the second electrode CE2 may be disposed on the plurality of light emitting devices ED. For example, the second electrode CE2 may include a transparent conductive oxide, but is not limited thereto. For example, the second electrode CE2 may be disposed to be in contact with or directly in contact with the cathode electrode 135. For example, the second electrode CE2 may overlap an entire of the first optical layer 117a and may overlap a portion of the second optical layer 117b. For example, the second electrode CE2 may be electrically connected to the contact electrode CCE through the second optical layer 117b. For example, the second electrode CE2 may be electrically connected to the contact electrode CCE through the contact hole formed in the second optical layer 117b.

The second electrode CE2 may be continuously extended along the row direction (or the first direction X) of the substrate 110. Accordingly, the second electrode CE2 may be commonly connected to the plurality of light emitting devices ED in each of the plurality of pixels PX arranged along the row direction (or the first direction X) of the substrate 110.

The second electrode CE2 may extend continuously over the first optical layer 117a, the second optical layer 117b, and the light emitting device ED. A region where the first optical layer 117a is disposed may include a concave portion which is recessed inwardly more than the upper surface of the second optical layer 117b. Accordingly, a first portion of the second electrode CE2 disposed on the first optical layer 117a may be disposed along the concave portion, and thus may be disposed at a lower position than a second portion of the second electrode CE2 disposed on the second optical layer 117b. For example, the thickness of the first optical layer 117a may progressively decrease from the second optical layer 117b toward a central portion (or a central portion) of the first optical layer 117a for electrical connection (or contact) between each of the first to third light emitting devices 130, 140, and 150 and the second electrode CE2.

The third optical layer 117c may be disposed on the second electrode CE2. The third optical layer 117c may be disposed on the second electrode CE2 so as to overlap with the plurality of light emitting devices ED and the first optical layer 117a. For example, the third optical layer 117c may be disposed so as not to overlap with the second optical layer 117b. Since the third optical layer 117c is disposed on the second electrode CE2 and the plurality of light emitting devices ED, it is possible to improve a stain mura that may occur in some of the plurality of light emitting devices ED. For example, when transferring the plurality of light emitting devices ED onto the substrate 110 of the display panel 100, an area in which an interval (or a spacing) between the plurality of light emitting devices ED is not uniform may occur due to process deviation, or the like. When the interval between the plurality of light emitting devices ED is non-uniform, an emission area of each of the plurality of light emitting devices ED may be non-uniformly formed, and thus, a mura may be visually recognized by the user. Accordingly, since the third optical layer 117c for uniformly diffusing light is additionally configured on an upper portion of the plurality of light emitting devices ED, the light emitted from some of the light emitting devices ED may be reduced or prevented from being visually recognized as the mura. Therefore, since the light emitted from the plurality of light emitting devices ED is uniformly diffused by the third optical layer 117c and extracted to the outside of the display panel 100, uniformity of luminance of the display apparatus may be improved.

The third optical layer 117c may be composed of an organic insulating material having fine particles 117cp dispersed therein, but is not limited thereto. For example, the third optical layer 117c may be composed of siloxane having fine particles 117cp such as titanium dioxide (TiO₂) particles dispersed therein, but is not limited thereto. For example, the third optical layer 117c may be composed of the same material as the first optical layer 117a, but is not limited thereto. For example, the third optical layer 117c may be a diffusion layer or a top diffusion layer, but is not limited thereto.

Light from a plurality of light emitting devices ED may be scattered by fine particles 117cp dispersed in the third optical layer 117c and emitted to the outside of the display panel 100. The third optical layer 117c may uniformly mix (or diffuse) light emitted from the plurality of light emitting devices ED, thereby further improving uniformity of luminance of the display apparatus. In addition, light extraction efficiency of the display apparatus may be improved by the light scattered by the fine particles 117cp, and thus the display apparatus may be driven at a low-power.

In the display area AA, a black matrix BM may be disposed on the second electrode CE2, the first optical layer 117a, the second optical layer 117b, and the third optical layer 117c.

The black matrix BM may be configured to include a plurality of openings (or light transmitting portions) overlapping each of the plurality of light emitting devices ED. For example, the black matrix BM may be formed (or configured) to cover the remaining display areas except for an area overlapping each of the plurality of light emitting devices ED. For example, the black matrix BM may fill the contact hole of the second optical layer 117b. Since the black matrix BM is configured to cover the display area AA, color mixing of light and external light reflection of the plurality of sub-pixels may be reduced. For example, the black matrix BM may also be disposed within the contact hole where the second electrode CE2 and the contact electrode CCE are connected, light leakage between the plurality of adjacent sub-pixels may be prevented. For example, the black matrix BM may be made of an opaque material, but is not limited thereto.

Referring to FIG. 8, the display apparatus 1000 according to one or more embodiments of the present disclosure may further include a cover layer 118.

The cover layer 118 may be configured to cover the display area AA. The cover layer 118 may be configured to cover the second electrode (or common electrode) CE2 disposed (or configured) in the display area AA. For example, the cover layer 118 may be disposed on the black matrix BM in the display area AA. For example, the black matrix BM may be disposed (or interposed) between the cover layer 118 and the optical layers 117a, 117b, and 117c.

The cover layer 118 may be configured to protect the plurality of light emitting devices ED. For example, the components (or layers) configured between the substrate 110 and the cover layer 118 may be protected by the substrate 110 and the cover layer 118. For example, the cover layer 118 may be configured of an organic insulating material or an inorganic insulating material. For example, the cover layer 118 may be an overcoating layer, a protection layer, or an insulating layer, or the like, but is are not limited thereto.

The polarizing layer 180 may be disposed (or configured) on the cover layer 118 by using a first adhesive layer 181. The cover member 120 may be disposed on the polarizing layer 180 by using a second adhesive layer 185.

A plurality of pad electrodes PE may be disposed on a third insulating layer 115c in the second non-display area NA2. For example, at least a portion of the plurality of pad electrodes PE may be exposed without being covered by the passivation layer 116. For example, the plurality of pad electrodes PE may be electrically connected to the 2-4^{th} connection line 122d through a contact hole of the third insulating layer 115c.

An adhesive film ACF may be disposed on the plurality of pad electrodes PE. The adhesive film ACF may be an adhesive layer in which conductive balls are dispersed on an insulating material, but is not limited thereto. When heat and/or pressure is applied to the adhesive film ACF, the conductive balls may be electrically connected at a portion where the heat and/or pressure is applied, thereby having conductive characteristics. By disposing the adhesive film ACF between the plurality of pad electrodes PE and the flexible circuit board (or flexible film) 310, the flexible circuit board (or flexible film) 310 may be attached or bonded to the plurality of pad electrodes PE.

The flexible circuit board 310 may be placed on the adhesive film ACF. The flexible circuit board 310 may be electrically connected to a plurality of pad electrodes PE through the adhesive film ACF. Accordingly, signals output from the flexible circuit board 310 and the printed circuit board 330 may be transmitted to the pixel driving circuit PD in the display area AA through the wiring layer. For example, signals output from the printed circuit board 330 may be transmitted to the pixel driving circuit PD in the display area AA through the flexible circuit board 310, the plurality of pad electrodes PE, the 2-4^{th} connection line 122d, the 2-3^{th} connection line 122c, the 2-2^{th} connection line 122b, and the 2-1^{th} connection line 122a.

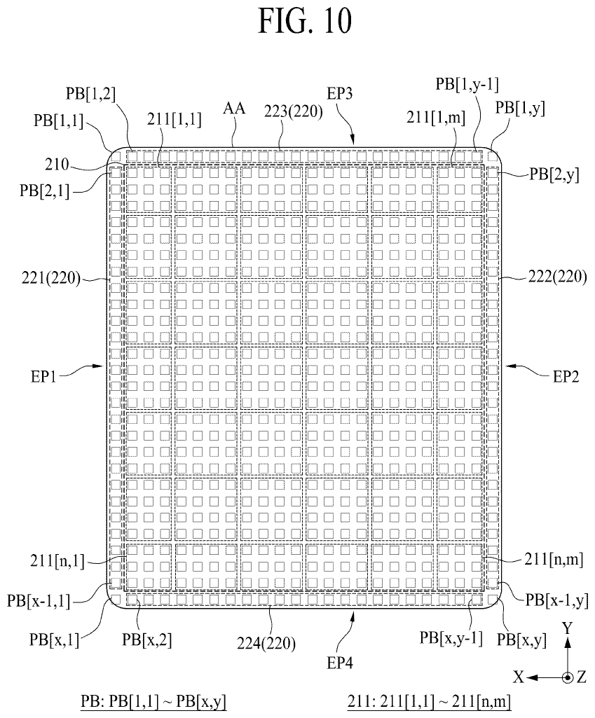

FIG. 10 is a diagram illustrating first and second touch electrode parts according to one or more embodiments of the present disclosure.

Referring to FIG. 10, the display apparatus according to one or more embodiments of the present disclosure may include a first touch electrode part 210 and a second touch electrode part 220 disposed (or configured) in the display area AA.

The display area AA may include a plurality of pixel block rows, a plurality of pixel block columns, and first to fourth edge portions EP1 to EP4.

The plurality of pixel block rows (or horizontal block lines) may be horizontal lines of the display area AA. The plurality of pixel block columns (or vertical block lines) may be a vertical line of the display area AA. For example, the display area AA may include first to x^{th} pixel block rows and first to y^{th} pixel block columns.

Each of the plurality of pixel block rows may include a plurality of pixel blocks PB disposed (or configured) to have a predetermined interval. Accordingly, the display area AA may include a plurality of pixel blocks PB[1,1] to PB[x,y] disposed (or configured) to have a matrix form having x rows and y columns.

In the display area AA, a first edge portion (or a left edge portion) EP1 may be adjacent to a first side of a substrate, a second edge portion (or a right edge portion) EP2 may be adjacent to a second side opposite to the first side of the substrate, a third edge portion (or an upper edge portion) EP3 may be adjacent to a third side of the substrate, and a fourth edge portion (or a lower edge portion) EP4 may be adjacent to a fourth side opposite to the third side of the substrate.

Each of the first and second edge portions EP1 and EP2 of the display area AA may include one or more pixel block rows, and each of the third and fourth edge portions EP3 and EP4 of the display area AA may include one or more pixel block columns, but is not limited thereto. Each of the first and second edge portions EP1 and EP2 of the display area AA may include a plurality of pixel blocks PB disposed (or configured) in one or more pixel block rows, and each of the third and fourth edge portions EP3 and EP4 of the display area AA may include a plurality of pixel blocks PB disposed (or configured) in one pixel block column.

Each of the first and second edge portions EP1 and EP2 of the display area AA may include one pixel block row, and each of the third and fourth edge portions EP3 and EP4 of the display area AA may include one pixel block column. For example, in the display area AA, the first edge portion EP1 may include a first pixel block column, the second edge portion EP2 may include a y^{th} pixel block column, the third edge portion EP3 may include a first pixel block row, and the fourth edge portion EP4 may include an x^{th} pixel block row. For example, the first edge portion EP1 of the display area AA may include a plurality of pixel blocks PB[1,1], PB[2,1] to PB[x,1] disposed in the first pixel block column. The second edge portion EP2 of the display area AA may include a plurality of pixel blocks PB[1,y], PB[2,y] to PB[x,y] disposed in the y^{th} pixel block column. The third edge portion EP3 of the display area AA may include a plurality of pixel blocks PB[1,1] to PB[1,y] disposed in the first pixel block row. The fourth edge portion EP4 of the display area AA may include a plurality of pixel blocks PB[x,1] to PB[x,y] disposed in the x^{th} pixel block row.

The first touch electrode part 210 may be an element (or an area) for sensing a user's contact touch (or a user's direct contact touch). The first touch electrode part 210 may be disposed (or configured) in an intermediate portion of the display area AA. For example, the first touch electrode part 210 may be disposed (or configured) in the intermediate portion of the display area AA except for the first to fourth edge portions EP1, EP2, EP3, and EP4.

The first touch electrode part 210 may include the remaining pixel blocks PB except for the pixel blocks PB disposed (or configured) in each of the first to fourth edge portions EP1, EP2, EP3, and EP4 of the display area AA among the plurality of pixel blocks PB[1,1] to PB[x,y]. For example, the first touch electrode part 210 may include a plurality of pixel blocks PB disposed (or configured) in the intermediate portion of the display area AA. For example, the first touch electrode part 210 may include pixel blocks PB[2,2] to PB[x−1, y−1] from a 2^{th} row and a 2^{th} column (2,2) to an (x−1)^{th} row and a (y−1)^{th} column (x−1, y−1) among the plurality of pixel blocks PB[1,1] to PB[x,y].

The first touch electrode part 210 according to one or more embodiments of the present disclosure may include a plurality of contact touch electrodes 211. The first touch electrode part 210 may include a plurality of contact touch electrodes 211 disposed in the intermediate portion of the display area AA to have a plurality of rows and a plurality of columns. For example, the plurality of contact touch electrodes 211 may be a plurality of contact touch areas. For example, the plurality of contact touch electrodes 211 may have the same size, or some of the plurality of contact touch electrodes 211 may have different sizes.

The first touch electrode part 210 may include the plurality of contact touch electrodes 211[1,1] to 211[n,m] disposed (or configured) to have a matrix form having n rows and m columns. For example, the first touch electrode part 210 may include first to n×m contact touch electrodes 211[1,1] to 211[n,m].

Some of the plurality of contact touch electrodes 211[1,1] to 211[n,m] may have different sizes. For example, a contact touch electrode 211 disposed at an edge portion of the first touch electrode part 210 may have a relatively smaller size than a contact touch electrode 211 disposed at an intermediate portion of the first touch electrode part 210. Among the plurality of contact touch electrodes 211[1,1] to 211[n,m], the contact touch electrodes disposed in the first column 211[1,1] to 211[n,1] (hereinafter, referred to as “first edge contact touch electrodes”), the contact touch electrodes disposed in the m^{th} column 211[1,m] to 211[n,m]) (hereinafter, referred to as “second edge contact touch electrodes”), the contact touch electrodes disposed in the first row 211[1,1] to 211[1,m] (hereinafter, referred to as “third edge contact touch electrodes”), and the contact touch electrodes disposed in the n^{th} row 211[n,1] to 211[n,m] (hereinafter, referred to as “fourth edge contact touch electrodes”) may each have a smaller size than the contact touch electrodes disposed from the 2^{th} row and the 2^{th} column (2,2) to the (n−1)^{th} row and (m−1)^{th} column 211[2,2] to 211[n−1,m−1] (hereinafter, referred to as “center contact touch electrodes”).

The center contact touch electrodes 211[2,2] to 211[n−1,m−1] may have the same size. Each of the first edge contact touch electrodes 211[1,1] to 211[n,1], the second edge contact touch electrodes 211[1,m] to 211[n,m], the third edge contact touch electrodes 211[1,1] to 211[1,m], and the fourth edge contact touch electrodes 211[n,1] to 211[n,m] may have a smaller size than the center contact touch electrodes 211[2,2] to 211[n−1,m−1]. Each of the contact touch electrodes 211[1,1], 211[1,m], 211[n,1], and 211[n,m] (hereinafter, referred to as “corner contact touch electrodes”) disposed at the first row and first column (1,1), the first row and m^{th} column (1,m), the n^{th} row and first column (n,1), and the n^{th} row and m^{th} column (n,m) may have the smallest size.

Each of the plurality of contact touch electrodes 211 may include the plurality of pixel blocks PB. Each of the plurality of contact touch electrodes 211 may be configured (or formed) by a plurality of second electrodes disposed (or configured) in each of the plurality of pixel blocks PB. For example, the plurality of second electrodes disposed (or configured) in each of the plurality of pixel blocks PB may configure (or form) one contact touch electrode 211 or may be driven as one contact touch electrode 211.

The center contact touch electrodes 211[2,2] to 211[n−1,m−1] may include the same number of pixel blocks PB. For example, each of the center contact touch electrodes 211[2,2] to 211[n−1,m−1] may include sixteen pixel blocks PB disposed in a matrix form having four

rows and four columns, but is not limited thereto. Each of the center contact touch electrodes 211[2,2] to 211[n−1,m−1] may be configured (or driven) by the plurality of second electrodes disposed (or configured) in each of the sixteen pixel blocks PB, but is not limited thereto.

Each of the first edge contact touch electrodes 211[1,] to 211[n,1]), the second edge contact touch electrodes 211[1,m] to 211[n,m], the third edge contact touch electrodes 211[1,1] to 211[1,m], and the fourth edge contact touch electrodes 211[n,1] to 211[n,m] may include the same number of pixel blocks PB. For example, each of the first edge contact touch electrodes 211[1,1] to 211[n,m] and the second edge contact touch electrodes 211[1,m] to 211[n,m] may include twelve pixel blocks PB disposed in a matrix form having four rows and three columns, but is not limited thereto. Each of the third edge contact touch electrodes 211[1,1] to 211[n,m] and the fourth edge contact touch electrodes 211[n,1] to 211[n,m] may include twelve pixel blocks PB disposed in a matrix form having three rows and four columns, but is not limited thereto. Each of the first edge contact touch electrodes 211[1,1] to 211[n,1], the second edge contact touch electrodes 211[1,m] to 211[n,m], the third edge contact touch electrodes 211[1,1] to 211[1,m], and the fourth edge contact touch electrodes 211[n,1] to 211[n,m] may be configured (or driven) by the plurality of second electrodes disposed (or configured) in each of the twelve pixel blocks PB, but is not limited thereto.

The corner contact touch electrodes 211[1,1], 211[1,m], 211[n,1], and 211[n,m] may include the same number of pixel blocks PB. For example, each of the corner contact touch electrodes 211[1,1], 211[1,m], 211[n,1], and 211[n,m] may include nine pixel blocks PB disposed in a matrix form having three rows and three columns, but is not limited thereto. Each of the corner contact touch electrodes 211[1,1], 211[1,m], 211[n,1], and 211[n,m] may be configured (or driven) by the plurality of second electrodes disposed (or configured) in each of the nine pixel blocks PB, but is not limited thereto.

In a first touch mode based on a self-capacitance method, each of the plurality of contact touch electrodes 211[1,1] to 211[n,m] may be driven as a touch driving/sensing electrode, but is not limited thereto.

In the first touch mode based on the mutual capacitance method, some of the plurality of contact touch electrodes 211[1,1] to 211[n,m] may be driven by a touch driving electrode, and the remaining electrodes of contact touch electrodes 211[1,1] to 211[n,m] may be driven by a touch sensing electrode. In this case, the contact touch electrodes driven as the touch driving electrode and the contact touch electrodes driven as the touch sensing electrode may be alternately disposed in the first direction X and the second direction Y, respectively, within the first touch electrode part 210.

Each of the plurality of contact touch electrodes 211[1,1] to 211[n,m] may be driven as a hover touch driving electrode (or a hover touch driving area) in the second touch mode. For example, in the second touch mode, the plurality of contact touch electrodes 211[1,1] to 211[n,m] may be driven as one hover touch driving electrode.

The plurality of second electrodes disposed (or configured) in the pixel blocks PB included (or disposed) in each of the plurality of contact touch electrodes 211[1,1] to 211[n,m] may be used (or driven) as one or more of the touch driving electrode and the touch sensing electrode in the first touch mode, and may be used (or driven) as the hover touch driving electrode in the second touch mode.

The second touch electrode part 220 may be an element (or an area) for sensing a user's non-contact touch (or a user's hover touch). The second touch electrode part 220 may be disposed (or configured) at an edge portion of the display area AA. For example, the second touch electrode part 220 may be disposed (or configured) at the first to fourth edge portions EP1, EP2, EP3, and EP4 of the display area AA.

The second touch electrode part 220 may include pixel blocks PB disposed (or configured) at each of the first to fourth edge portions EP1, EP2, EP3, and EP4 of the display area AA among the plurality of pixel blocks PB[1,1] to PB[x,y]. For example, the second touch electrode part 220 may include the remaining pixel blocks PB except for pixel blocks PB[1,1], PB[1,y], PB[x,1], and PB[x,y] disposed at corner portions of the display area AA among the pixel blocks PB disposed (or configured) in each of first to fourth edge portions EP1, EP2, EP3, and EP4 of the display area AA. For example, the second touch electrode part 220 may include the remaining pixel blocks PB except for pixel blocks PB[1,1], PB[1,y], PB[x,1], and PB[x,y] disposed at the corner portions of the display area AA among the plurality of pixel blocks PB[1,1] to PB[x,y] and the pixel blocks PB[2,2] to PB[x−1,y−1]) disposed in the first touch electrode part 210.

The second touch electrode part 220 may include a plurality of non-contact touch electrodes 221, 222, 223, and 224. The second touch electrode part 220 may include first to fourth non-contact touch electrodes 221, 222, 223, and 224. For example, each of the plurality of non-contact touch electrodes 221, 222, 223, and 224 or the first to fourth non-contact touch electrodes 221, 222, 223, and 224 may be a non-contact touch region.

The first non-contact touch electrode 221 may be disposed (or configured) at the first edge portion EP1 of the display area AA. The first non-contact touch electrode 221 may include the plurality of pixel blocks PB. The plurality of second electrodes configured in pixel blocks PB included in one or more pixel block columns disposed in the first edge portion EP1 of the display area AA may configure (or form) the first non-contact touch electrode 221 or may be driven as the first non-contact touch electrode 221. For example, the plurality of second electrodes configured in pixel blocks PB included in the first pixel block column of the display area AA may be driven as the first non-contact touch electrode 221. For example, the plurality of second electrodes configured in pixel blocks PB[2,1] to PB[x−1,1] disposed at the 2^{th} to (x−1)^{th} rows of the first pixel block column may be driven as the first non-contact touch electrode 221 or as one first non-contact touch electrode 221.

The second non-contact touch electrode 222 may be disposed (or configured) at the second edge portion EP2 of the display area AA. The second non-contact touch electrode 222 may include the plurality of pixel blocks PB. The plurality of second electrodes configured in pixel blocks PB included in one or more pixel block columns disposed in the second edge portion EP2 of the display area AA may configure (or form) the second non-contact touch electrode 222 or may be driven as the second non-contact touch electrode 222. For example, the plurality of second electrodes configured in pixel blocks PB included in the y^{th} pixel block column of the display area AA may be driven as the second non-contact touch electrode 222. For example, the plurality of second electrodes configured in pixel blocks PB[2,y] to PB[x−1,y] disposed at the 2^{th} to (x−1)^{th} rows of the y^{th} pixel block column may be driven as the second non-contact touch electrode 222 or as one second non-contact touch electrode 222.

The third non-contact touch electrode 223 may be disposed (or configured) at the third edge portion EP3 of the display area AA. The third non-contact touch electrode 223 may include the plurality of pixel blocks PB. The plurality of second electrodes configured in pixel blocks PB included in one or more pixel block rows disposed in the third edge portion EP3 of the display area AA may configure (or form) the third non-contact touch electrode 223 or may be driven as the third non-contact touch electrode 223. For example, the plurality of second electrodes configured in pixel blocks PB included in the first pixel block row of the display area AA may be driven as the third non-contact touch electrode 223. For example, the plurality of second electrodes configured in pixel blocks PB[1,2] to PB[1, y−1] disposed at the 2^{th} to (y−1)^{th} columns of the first pixel block row may be driven as the third non-contact touch electrode 223 or as one third non-contact touch electrode 223.

The fourth non-contact touch electrode 224 may be disposed (or configured) at the fourth edge portion EP4 of the display area AA. The fourth non-contact touch electrode 224 may include the plurality of pixel blocks PB. The plurality of second electrodes configured in pixel blocks PB included in one or more pixel block rows disposed in the fourth edge portion EP4 of the display area AA may configure (or form) the fourth non-contact touch electrode 224 or may be driven as the fourth non-contact touch electrode 224. For example, the plurality of second electrodes configured in pixel blocks PB included in the x^{th} pixel block row the display area AA may be driven as the fourth non-contact touch electrode 224. For example, the plurality of second electrodes configured in pixel blocks PB[x,2] to PB[x, y−1] disposed at the 2^{th} to (y−1)^{th} columns of the x^{th} pixel block row may be driven as the fourth non-contact touch electrode 224 or as one fourth non-contact touch electrode 224.

Each of the plurality of (or first to fourth) non-contact touch electrodes 221, 222, 223, and 224 may configure (or form) a hover touch sensing electrode or may be driven as a hover touch sensing electrode in the second touch mode. For example, in the second touch mode, each of the first to fourth non-contact touch electrodes 221, 222, 223, and 224 may be driven as a hover touch sensing electrode for sensing a user's non-contact touch on edge portions of the display area AA.

When the first non-contact touch electrode 221 is driven by a first hover touch sensing electrode, the second non-contact touch electrode 222 is driven by a second hover touch sensing electrode, the third non-contact touch electrode 223 is driven by a third hover touch sensing electrode, and the fourth non-contact touch electrode 224 may be driven by a fourth hover touch sensing electrode. For example, the first non-contact touch electrode 221 and the second non-contact touch electrode 222 may be driven to sense a user's non-contact gesture moving from the first edge portion EP1 to the second edge portion EP2 of the display area AA. For example, the third non-contact touch electrode 223 and the fourth non-contact touch electrode 224 may be driven to sense a user's non-contact gesture moving from the third edge portion EP3 to the fourth edge portion EP4 of the display area AA.

Each of the plurality of (or first to fourth) non-contact touch electrodes 221, 222, 223, and 224 may be used (or driven) as a touch guard electrode receiving an auxiliary driving signal or a touch shield electrode receiving a constant direct-current (DC) voltage in the first touch mode.

The pixel blocks PB[1,1], PB[1,y], PB[x,1], and PB[x,y] disposed in the corner portion of the display area AA may not be included in the first touch electrode part and the second touch electrode part, but are not limited thereto. For example, each of the pixel blocks PB[1,1], PB[1,y], PB[x,1], and PB[x,y] disposed at each of the first row and first column (1,1), the first row and y^{th} column (1,y), the x^{th} row and first column (x,1), and the x^{th} row and y^{th} column (x,y) may not be included in the first touch electrode part and the second touch electrode part, but are not limited thereto. For example, the pixel blocks PB[1,1] disposed in the first row and first column (1,1) may be included in the contact touch electrodes 211[1,1] disposed at the first row and first column (1,1) of the first touch electrode part. The pixel blocks PB[1,y] disposed in the first row and y^{th} column (1,y) may be included in the contact touch electrodes 211[1,m] disposed at the first row and m^{th} column (1,m) of the first touch electrode part. The pixel blocks PB[x,1] disposed in the x^{th} row and first column (x,1) may be included in the contact touch electrodes 211[n,1] disposed at the n^{th} row and first column (n,1) of the first touch electrode part. The pixel blocks PB[x,y] disposed in the x^{th} row and y^{th} column (x,y) may be included in the contact touch electrodes 211[1,y] disposed at the n^{th} row and m^{th} column (n,m) of the first touch electrode part.

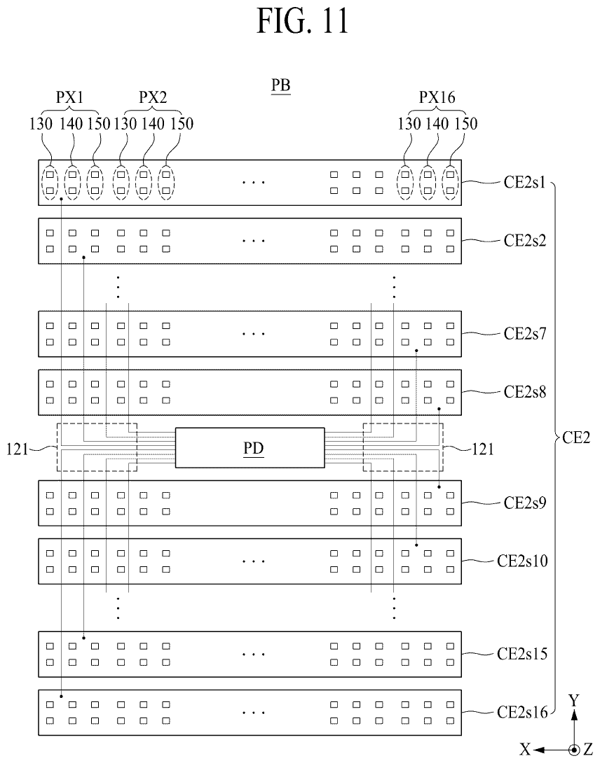

FIG. 11 is a diagram illustrating one pixel block illustrated in FIG. 10.

Referring to FIGS. 10 and 11, in the display apparatus according to one or more embodiments of the present, one pixel block PB may include a plurality of pixels PX1 to PX16, a second electrode CE2, and a pixel driving circuit PD.

The plurality of pixels PX1 to PX16 may be disposed in a predetermined interval along the first direction X, and may be disposed in a predetermined interval along the second direction Y. For example, the plurality of pixels PX1 to PX16 may be disposed in a matrix form having a plurality of rows and a plurality of columns. For example, the plurality of pixels PX1 to PX16 may be disposed to have sixteen rows and sixteen columns. In this case, the one pixel block PB may include the first to sixteenth pixel lines (or pixel rows).

Each of the plurality of pixels PX1 to PX16 may include first to third light emitting devices 130, 140, and 150. The first to third light emitting devices 130, 140, and 150 may be repeatedly or alternately disposed in the order of red, green, and blue sub-pixels in each of the first to sixteenth pixel lines, but are not limited thereto. For example, the red, green, and blue sub-pixels may be disposed at the same column in each of the first to sixteenth pixel lines.

The second electrode CE2 may be disposed in a predetermined interval along the second direction Y. The second electrode CE2 may be disposed at the first to sixteenth pixel lines, respectively, and may be electrically connected to each of a plurality of first to third light emitting devices 130, 140, and 150.

The second electrode CE2 may include first to sixteenth sub-electrodes CE2s1 to CE2s16.

Each of the first to sixteenth sub-electrodes CE2s1 to CE2s16 may have a line shape. Each of the first to sixteenth sub-electrodes CE2s1 to CE2s16 may be electrically separated within the pixel block PB. Each of the first to sixteenth sub-electrodes CE2s1 to CE2s16 may be electrically separated within the pixel block PB by electrode patterning of the second electrode CE2. The first to sixteenth sub-electrodes CE2s1 to CE2s16 may be electrically connected to the plurality of first to third light emitting devices 130, 140, and 150, respectively. For example, one sub-electrode CE2s1 to CE2s16 may be commonly connected to sixteen first light emitting devices 130, sixteen second light emitting devices 140, and sixteen third light emitting devices 150, respectively.

The pixel driving circuit PD may be disposed within the pixel block PB. For example, although FIG. 11 illustrates that the pixel driving circuit PD is disposed between two adjacent sub-electrodes CE2s8 and CE2s9, but is not limited thereto. For example, the pixel driving circuit PD may be disposed to overlap one or more sub-electrodes CE2s7 to CE2s10 disposed at a central portion (or a central portion) of the pixel block PB. For example, the pixel driving circuit PD may be disposed between one or more sub-electrodes CE2s7 to CE2s10 and a substrate.

Referring to FIGS. 3, 5, and 11, the pixel driving circuit PD may be configured to be electrically connected to the plurality of pixels PX1 to PX16 through a plurality of signal lines. The pixel driving circuit PD may be configured to drive the plurality of light emitting devices 130, 140, and 150 disposed in the first to sixteenth pixel lines. The pixel driving circuit PD may be configured to control a light emitting operation of the plurality of light emitting devices 130, 140, and 150 by supplying a signal and power to the plurality of pixels PX1 to PX16 disposed in each of the first to sixteenth pixel lines.

The pixel driving circuit PD may be configured to individually connect a plurality of first connection lines 121 to a plurality of sub-electrodes CE2s1 to CE2s16.

In the display mode, the pixel driving circuit PD may control the light emitting operation of the plurality of light emitting devices 130, 140, and 150 by sequentially supplying a cathode voltage to the first to sixteenth sub-electrodes CE2s1 to CE2s16 and simultaneously supplying an anode voltage (or data current) to the plurality of light emitting devices 130, 140, and 150 disposed in each of the first to sixteenth pixel lines.

In the first touch mode or the second touch mode, the plurality of sub-electrodes CE2s1 to CE2s16 configured at pixel blocks PB disposed in an intermediate portion of the display area among the plurality of pixel blocks PB may be driven by a contact touch electrode. In the first touch mode or the second touch mode, the plurality of sub-electrodes CE2s1 to CE2s16 configured at pixel blocks PB disposed in edge portions of the display area among the plurality of pixel blocks PB may be driven by a non-contact touch electrode. For example, when the pixel block PB is included (or disposed) in the first touch electrode part, the pixel driving circuit PD may drive the first to sixteenth sub-electrodes CE2s1 to CE2s16 to any one of one touch driving electrode and one touch sensing electrode in the first touch mode. Furthermore, when the pixel block PB is included (or disposed) in the second touch electrode part, the pixel driving circuit PD may drive the first to sixteenth sub-electrodes CE2s1 to CE2s16 to one touch sensing electrode in the second touch mode.

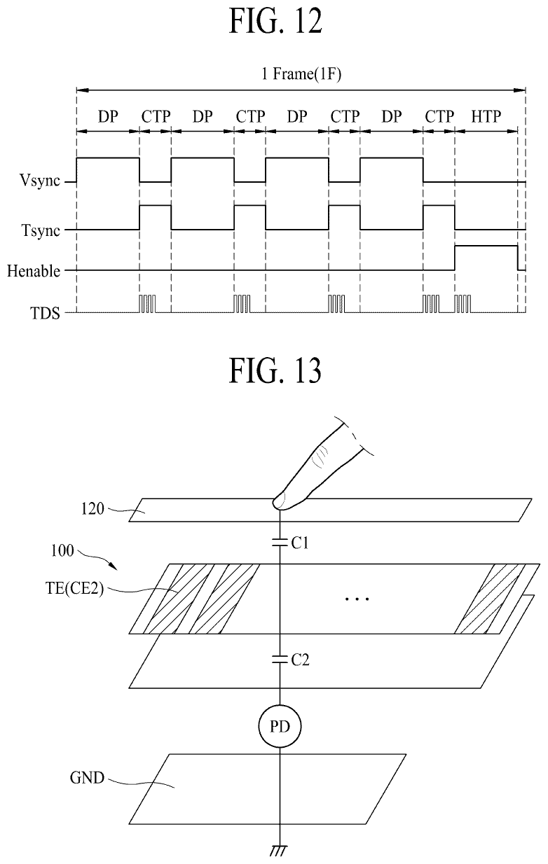

FIG. 12 is a diagram illustrating a display period and a touch sensing period of a display apparatus according to one or more embodiments of the present disclosure.

Referring to FIG. 12, the display apparatus according to one or more embodiments of the present disclosure may be configured to display an image in units of a frame period.

One frame period 1F may be divided (or time-divided) into a display period DP, a contact touch sensing period CTP, and a non-contact touch sensing period HTP. For example, one frame period 1F may be driven for a plurality of display periods DP, a plurality of contact touch periods CTP, and one or more non-contact touch periods HTP.

Each of the plurality of display periods DP may be a period for displaying an image on the display panel. Each of the plurality of contact touch periods (or contact touch sensing period) CTP may be a period for sensing a user's contact touch during a period between the plurality of display periods DP. The contact touch period CTP may be shorter than one display period DP. The non-contact touch period HTP may be a hover touch period.

The non-contact touch period (or a non-contact touch sensing period or a hover touch sensing period) HTP may be a period for sensing a user's non-contact touch. For example, the non-contact touch period HTP may be a period after a last contact touch period CTP among the plurality of contact touch periods CTP, but is not limited thereto. For example, the non-contact touch period HTP may be a period between a first display period DP and a second display period DP among the plurality of display periods DP. For example, the non-contact touch period HTP may be shorter than one display period DP and longer than the non-contact touch period HTP, but is not limited thereto.

In one frame period 1F, the cycle and order in which the display period DP and the contact touch period CTP are repeated may be variously changed.

In FIG. 12, Vsync may be a vertical synchronization signal (or a time-division control signal) for distinguishing the plurality of display periods DP, the plurality of contact touch sensing periods CTP, and one or more non-contact touch periods HTP. Tsync refers to a touch synchronization signal which is generated to correspond to each of the plurality of contact touch periods CTP. Henable refers to a hover enable signal which is generated to correspond to the non-contact touch period HTP. For example, the vertical synchronization signal Vsync, the touch synchronization signal Tsync, and the hover enable signal Henable may be generated by the driving integrated circuit (311 illustrated in FIG. 2), but are not limited thereto. For example, one or more of the vertical synchronization signal Vsync, the touch synchronization signal Tsync, and the hover enable signal Henable may be generated by the host control part of the display apparatus.

TDS refers to a touch driving signal that is synchronized with the touch synchronization signal Tsync and has one or more pulses. The touch driving signal TDS may be generated in each of the plurality of contact touch periods CTP and the non-contact touch period HTP. For example, the touch driving signal TDS may be generated in a power generating integrated circuit 370.

FIG. 13 is a diagram illustrating a touch sensing method in a display apparatus according to one or more embodiments of the present disclosure.

Referring to FIGS. 2 and 13, in the display apparatus according to one or more embodiments of the present disclosure, the second electrode CE2 may be used (or driven) as a touch electrode TE, and this structure is called an in-cell touch structure. Since the display apparatus according to one or more embodiments of the present disclosure does not include a separate touch electrode, the thickness of the display panel may be reduced.

The display apparatus or the driving integrated circuit 311 according to one or more embodiments of the present disclosure may perform touch driving and touch sensing based on a self-capacitance method, or may perform touch driving and touch sensing based on a mutual capacitance method. Furthermore, the display apparatus or the driving integrated circuit 311 according to one or more embodiments of the present disclosure may perform non-contact touch driving and non-contact touch sensing based on the mutual capacitance method.

When a user's finger or a touch pen directly contacts (or touches) the cover member 120, a first capacitance C1 between the second electrode CE2 provided on the display panel 100 and the cover member 120, and a second capacitance C2 between the second electrode CE2 and signal wires may be changed. A touch sensing signal generated by changes in the first capacitance C1 and the second capacitance C2 may be transmitted to the pixel driving circuit PD through the second electrode CE2. In this case, the pixel driving circuit PD may be connected to a ground part GND. The touch sensing signal transmitted to the pixel driving circuit PD may be transmitted to the driving integrated circuit 311, and the driving integrated circuit 311 may be configured to determine whether a touch has occurred on the touch electrode TE based on one or more touch sensing signals transmitted from one or more pixel driving circuits PD.

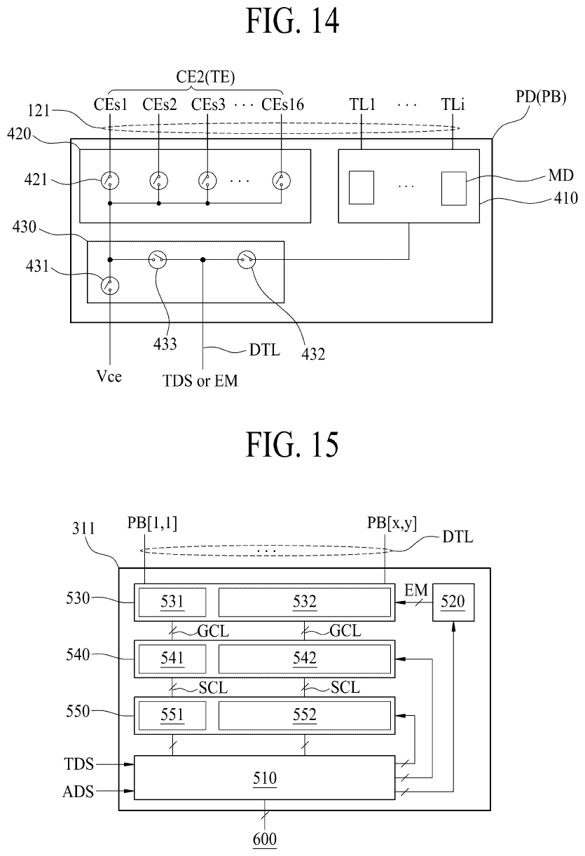

FIG. 14 is a diagram illustrating a pixel driving circuit according to one or more embodiments of the present disclosure.

Referring to FIGS. 2, 10, and 14, the pixel driving circuit PD according to one or more embodiments of the present disclosure may be electrically connected to a driving circuit part 300 through a data transmission line DTL.

The driving circuit part 300 (or driving integrated circuit 311) may be electrically connected to the pixel driving circuit PD disposed in each of a plurality of pixel blocks PB through a plurality of data transmission lines DTL. For example, the driving circuit part 300 (or driving integrated circuit 311) may be electrically connected to the pixel driving circuit PD disposed in each of the plurality of pixel blocks PB through the plurality of data transmission lines DTL.

In a display period according to a display mode, the driving circuit part 300 (or driving integrated circuit 311) may be configured to supply an emission signal (or a grayscale signal) and a cathode voltage Vce to the pixel driving circuit PD disposed in each of the plurality of pixel blocks PB through the plurality of data transmission lines DTL.

In a contact touch period according to a first touch mode, the driving circuit part 300 (or driving integrated circuit 311) may be configured to supply a touch driving signal to the pixel driving circuit PD disposed in each of the plurality of pixel blocks PB included in the first touch electrode part through the plurality of data transmission lines DTL, but is not limited thereto. For example, in the contact touch period according to the first touch mode, the driving circuit part 300 (or driving integrated circuit 311) may be configured to supply the touch driving signal to the pixel driving circuit PD disposed in each of the plurality of pixel blocks PB included in the first touch electrode part through a separate touch driving signal line.

In a non-contact touch period according to a second touch mode, the driving circuit part 300 (or driving integrated circuit 311) may be configured to supply an auxiliary driving signal to the pixel driving circuit PD disposed in each of the plurality of pixel blocks PB included in the first touch electrode part through the plurality of data transmission lines DTL, but is not limited thereto. For example, in the non-contact touch period according to the second touch mode, the driving circuit part 300 (or driving integrated circuit 311) may be configured to supply the auxiliary driving signal to the pixel driving circuit PD disposed in each of the plurality of pixel blocks PB included in the first touch electrode part through a separate touch driving signal line.

The driving circuit part 300 (or driving integrated circuit 311) may be configured to apply the touch driving signal to each of the plurality of contact touch electrodes through the pixel driving circuits PD of the pixel blocks PB in the first touch mode, and to sense a contact touch through the plurality of contact touch electrodes and the pixel driving circuits PD of the pixel blocks PB. The driving circuit part 300 (or driving integrated circuit 311) may be configured to simultaneously apply the touch driving signal to the plurality of contact touch electrodes through the pixel driving circuits PD of the pixel blocks PB in the second touch mode, and to sense a non-contact touch through each of the plurality of non-contact touch electrodes and the pixel driving circuits PD of the pixel blocks PB.

The pixel driving circuit PD may be configured to sequentially apply the cathode voltage Vce to a plurality of sub-electrodes CE2s1 to CE2s16 disposed in each of the plurality of pixel blocks PB in the display mode. Accordingly, a plurality of light emitting devices connected to each of the plurality of sub-electrodes CE2s1 to CE2s16 may emit light when the cathode voltage Vce is applied. The pixel driving circuit PD may be configured to commonly connect the plurality of sub-electrodes CE2s1 to CE2s16 to corresponding data transmission lines among a plurality of data transmission lines in the first touch mode or the second touch mode. Accordingly, the plurality of sub-electrodes CE2s1 to CE2s16 may be used (or driven) as the touch electrode TE in the first touch mode or the second touch mode.

The pixel driving circuit PD according to one or more embodiments of the present disclosure may include a sub-pixel driving part 410, a cathode electrode driving part 420, and a switching part 430.

The sub-pixel driving part 410 may be configured to supply an anode voltage (or a data current) to a plurality of first electrodes configured in each of the plurality of sub-pixels in the display period according to the display mode.

The sub-pixel driving part 410 may be electrically connected to the plurality of first electrodes configured in each of the plurality of sub-pixels through a plurality of first connection lines 121 and a plurality of signal lines TL. The sub-pixel driving part 410 may be electrically connected to the driving circuit part 300 (or driving integrated circuit 311) through the data transmission line DTL. The sub-pixel driving part 410 may be configured to supply the anode voltage corresponding to an emission signal supplied from the driving circuit part 300 (or driving integrated circuit 311) to the plurality of first electrodes configured in each of the plurality of sub-pixels through the data transmission line DTL. To this end, the sub-pixel driving part 410 may include a plurality of micro-drivers MD. Since each of the plurality of micro-drivers MD is substantially the same as the micro-driver MD described with reference to FIG. 4, repeated descriptions thereof will be omitted.

The cathode electrode driving part 420 may be configured to supply the cathode voltage Vce or the touch driving signal to a plurality of second electrodes. The cathode electrode driving part 420 may be configured to electrically connect the plurality of first connection lines 121 to the plurality of sub-electrodes CE2s1 to CE2s16.

In the display period according to the display mode, the cathode electrode driving part 420 may be configured to sequentially supply the cathode voltage (or cathode-on voltage) Vce supplied from the power generating integrated circuit 370 to the plurality of sub-electrodes CE2s1 to CE2s16 configured in the pixel block PB.

In the contact touch period according to the first touch mode or the non-contact touch period according to the second touch mode, the cathode electrode driving part 420 may be configured to simultaneously supply the touch driving signal TDS supplied through the data transmission line DTL from the driving circuit part 300 (or driving integrated circuit 311) to the plurality of sub-electrodes CE2s1 to CE2s16.

In the contact touch period according to the first touch mode, the cathode electrode driving part 420 may be configured to simultaneously supply the auxiliary driving signal supplied from the driving circuit part 300 (or driving integrated circuit 311) through the data transmission line DTL to the plurality of sub-electrodes CE2s1 to CE2s16.

The cathode electrode driving part 420 according to one or more embodiments of the present disclosure may be configured to include a plurality of switching devices 421.

The plurality of switching devices 421 may be configured to individually connect the plurality of first connection lines 121 to the plurality of sub-electrodes CE2s1 to CE2s16.

In a display period according to the display mode, the plurality of switching devices 421 may be configured to be sequentially turned on based on a switching control signal corresponding to a light emission period of each of the first to sixteenth pixel lines, and to sequentially supply the cathode voltage Vce to the plurality of sub-electrodes CE2s1 to CE2s16.

In the contact touch period according to the first touch mode or the non-contact touch period according to the second touch mode, the plurality of switching devices 421s may be configured to be turned on simultaneously based on the switching control signal, and to simultaneously supply the touch drive signal TDS supplied through the data transmission line DTL to the plurality of sub-electrodes CE2s1 to CE2s16.

The switching part 430 may be configured to connect the data transmission line DTL to the cathode electrode driving part 420 or the sub-pixel driving part 410.

The switching part 430 according to one or more embodiments of the present disclosure may be configured to include a first switch 431, a second switch 432, and a third switch 433.

Each of the first to third switches 431, 432, and 433 may be turned on or turned off based on a switch control signal supplied (or transmitted) from the driving integrated circuit 311.

The first switch 431 may be configured to supply the cathode voltage Vce to the cathode electrode driving part 420. The first switch 431 may be turned on in the display period according to the display mode. For example, the first switch 431 may be configured to supply the cathode voltage Vce to the cathode electrode driving part 420 in the display period according to a vertical synchronization signal or a touch synchronization signal supplied from the driving integrated circuit 311. Accordingly, the cathode voltage Vce may be supplied to the second electrode CE2 including the plurality of sub-electrodes (CE2s1 to CE2s16) in the display period. The first switch 431 may be configured to be turned off in the contact touch period according to the first touch mode, and to be turned off in the non-contact touch period according to the second touch mode.

The second switch 432 may be configured to electrically connect the data transmission line DTL and the sub-pixel driving part 410 in the display period, or electrically separate the data transmission line DTL and the sub-pixel driving part 410 in the contact touch period or the non-contact touch period.

The second switch 432 may be turned on in the display period to electrically connect the data transmission line DTL and the sub-pixel driving part 410. For example, the second switch 432 may be configured to supply an emission signal EM supplied from the driving integrated circuit 311 through the data transmission line DTL to the sub-pixel driving part 410 in the display period. Accordingly, in the display period, the emission signal EM transmitted from the driving integrated circuit 311 through the data transmission line DTL may be supplied to the sub-pixel driving part 410, and the micro-driver MD of the sub-pixel driving part 410 may output the anode voltage corresponding to the emission signal EM to a light emitting device.

The second switch 432 may be turned off in the contact touch period or the non-contact touch period, thereby electrically disconnecting the data transmission line DTL from the sub-pixel driving part 410. Accordingly, in the contact touch period or the non-contact touch period, the touch driving signal TDS supplied to the data transmission line DTL from the driving integrated circuit 311 is not supplied to the sub-pixel driving part 410.

The third switch 433 may be configured to electrically connect the data transmission line DTL to the cathode electrode driving part 420 in the display period, or to electrically disconnect the data transmission line DTL from the cathode electrode driving part 420 in the contact touch period or the non-contact touch period.

The third switch 433 may be turned off in the display period to electrically disconnect the data transmission line DTL from the cathode electrode driving part 420. Accordingly, in the display period, the data transmission line DTL may be electrically connected to the sub-pixel driving part 410 through the second switch 432, so that the emission signal EM transmitted from the driving integrated circuit 311 through the data transmission line DTL may be supplied to the sub-pixel driving part 410.

The third switch 433 may be turned on in the contact touch period or the non-contact touch period to electrically connect the data transmission line DTL to the cathode electrode driving part 420. Accordingly, in the contact touch period, the touch driving signal TDS supplied to the data transmission line DTL from the driving integrated circuit 311 may be supplied (or transmitted) to the cathode electrode driving part 420 through the third switch 433, and a touch sensing signal output from the cathode electrode driving part 420 may be supplied (or transmitted) to the driving integrated circuit 311 through the third switch 433 and the data transmission line DTL.

Each of the first switch 431 and the second switch 432 of the first to third switches 431, 432, and 433 may be turned on in the display period, whereby the light emitting device configured in the pixel block PB may emit light. The third switch 433 of the first to third switches 431, 432, and 433 may be turned on in the display period, whereby the plurality of sub-electrodes CE2s1 to CE2s16 configured in the pixel block PB may be driven as one touch electrode.

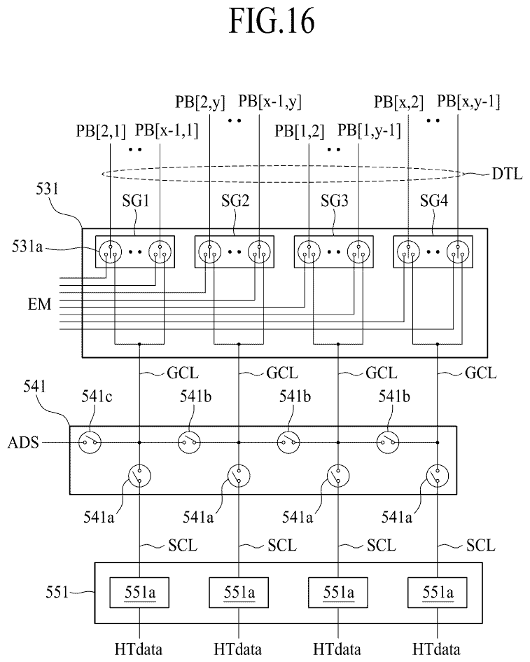

FIG. 15 is a diagram illustrating a driving integrated circuit according to one or more embodiments of the present disclosure. FIG. 16 is a diagram illustrating a first signal switching part, a first line connection part, and a first touch sensing part illustrated in FIG. 15. FIG. 17 is a diagram illustrating a second signal switching part, a second line connection part, and a second touch sensing part illustrated in FIG. 15.

Referring to FIGS. 10, 14, and 15, the driving circuit part 300 or the driving integrated circuit 311 according to one or more embodiments of the present disclosure may include a signal control part 510, an emission signal generating part 520, a signal switching part 530, a line connection part 540, and a touch sensing part 550.

The signal control part (or signal processing part or timing controller) 510 may be configured to receive image data and a timing synchronization signal provided from a host control part 600, to convert the image data into subpixel data, to provide the subpixel data to the emission signal generating part 520, and to control driving timing of the emission signal generating part 520, the signal switching part 530, the line connection part 540, and the touch sensing part 550 based on the timing synchronization signal. Furthermore, the signal control part 510 may be configured to control driving timing of each of pixel driving circuits PD provided in each of a plurality of pixel blocks PB[1,1] to PB[x,y]. The signal control part 510 may be configured to supply a touch driving signal TDS provided from the power generating integrated circuit to the touch sensing part 550, and to supply an auxiliary driving signal ADS provided from the power generating integrated circuit to the line connection part 540.

The emission signal generating part (or data processing part) 520 may be configured to convert data for each sub-pixel supplied from the signal control part 510 into emission signals for each sub-pixel EM, and to provide the emission signals for each sub-pixel EM to the signal switching part 530. For example, the emission signal generating part 520 may be configured to convert the image data for each sub-pixel into the emission signals for each sub-pixel EM including a duty-on period and a duty-off period based on a pulse width modulation PWM method.

The signal switching part 530 may be configured to supply the emission signal EM to each of a plurality of data transmission lines DTL in a display mode. In a first touch mode, the signal switching part 530 may be configured to electrically connect each of a first group of data transmission lines which are connected to each of a plurality of contact touch electrodes among the plurality of data transmission lines DTL to the touch sensing part 550 through the line connection part 540. In a second touch mode, the signal switching part 530 may be configured to electrically connect each of a second group of data transmission lines which are connected to each of a plurality of non-contact touch electrodes among the plurality of data transmission lines DTL to the touch sensing part 550 through the line connection part 540.

The signal switching part 530 may be individually connected to pixel driving circuits PD configured in each of the pixel blocks PB[1,1] to PB[x,y] through the data transmission lines DTL. In addition, the signal switching part 530 may be configured to connect the plurality of data transmission lines DTL to the line connection part 540. The signal switching part 530 may be configured to supply the emission signal EM supplied from the emission signal generating part 520 to the corresponding pixel driving circuits PD through the corresponding data transmission lines DTL in a display period under the control of the signal control part 510. The signal switching part 530 may be configured to connect the corresponding data transmission line DTL to the line connection part 540 in a contact touch period or a non-contact touch period under the control of the signal control part 510.

The signal switching part 530 according to one or more embodiments of the present disclosure may include a first signal switching part 531 and a second signal switching part 532.

Referring to FIGS. 10 and 14 to 16, the first signal switching part 531 may include a plurality of first signal switches 531a configured to be electrically connected to pixel driving circuits PD disposed in each of the plurality of pixel blocks PB included in the second touch electrode part 220 through the plurality of data transmission lines DTL.

The plurality of first signal switches 531a may be included in each of a plurality of switch groups SG1, SG2, SG3, and SG4. For example, the first signal switching part 531 may include first to fourth switch groups SG1, SG2, SG3, and SG4. Each of the first to fourth switch groups SG1, SG2, SG3, and SG4 may include a plurality of first signal switches 531a.

The plurality of first signal switches 531a included in the first switch group SG1 may be individually connected to a plurality of pixel driving circuits PD configured in each of the plurality of pixel blocks PB[2,1] to PB[x−1,1] disposed in a first edge portion EP1 of the display area AA through the plurality of data transmission lines DTL. For example, the plurality of first signal switches 531a included in the first switch group SG1 may finally be connected to a first non-contact touch electrode 221.

The plurality of first signal switches 531a included in the second switch group SG2 may be individually connected to a plurality of pixel driving circuits PD configured in each of the plurality of pixel blocks PB[2,y] to PB[x−1,y] disposed in a second edge portion EP2 of the display area AA through the plurality of data transmission lines DTL. For example, the plurality of first signal switches 531a included in the second switch group SG2 may finally be connected to a second non-contact touch electrode 222.

The plurality of first signal switches 531a included in the third switch group SG3 may be individually connected to a plurality of pixel driving circuits PD configured in each of the plurality of pixel blocks PB[1,2] to PB[1,y−1] disposed in a third edge portion EP3 of the display area AA through the plurality of data transmission lines DTL. For example, the plurality of first signal switches 531a included in the third switch group SG3 may finally be connected to a third non-contact touch electrode 223.

The plurality of first signal switches 531a included in the fourth switch group SG4 may be individually connected to a plurality of pixel driving circuits PD configured in each of the plurality of pixel blocks PB[x,2] to PB[x,y−1] disposed in a fourth edge portion EP4 of the display area AA through the plurality of data transmission lines DTL. For example, the plurality of first signal switches 531a included in the fourth switch group SG4 may finally be connected to a fourth non-contact touch electrode 224.

Each of the plurality of first signal switches 531a included in each of the first to fourth switch groups SG1, SG2, SG3, and SG4 may be configured to supply the emission signal EM supplied from the emission signal generating part 520 to the corresponding pixel driving circuits PD through the corresponding data transmission lines DTL in the display period under the control of the signal control part 510. In the display period, one emission signal EM may be supplied to the pixel driving circuit PD through the first signal switch 531a and the data transmission line DTL, and may be converted into an anode voltage in the pixel driving circuit PD to be supplied to the light emitting device.

Each of the plurality of first signal switches 531a included in each of the first to fourth switch groups SG1, SG2, SG3, and SG4 may be configured to commonly connect the plurality of data transmission lines DTL to one group common line GCL in the contact touch period or the non-contact touch period under the control of the signal control part 510. For example, a plurality of sub-electrodes CE2s1 to CE2s16 configured in each of the plurality of pixel blocks PB disposed in edge portions EP1, EP2, EP3, and EP4 of the display area AA may be commonly connected to the one group common line GCL, and thus, may be driven as the non-contact touch electrode (or non-contact touch sensing electrode).

The plurality of sub-electrodes CE2s1 to CE2s16 configured in each of the plurality of pixel blocks PB[2,1] to PB[x−1,1] disposed in the first edge portion EP1 of the display area AA may be commonly connected to the one group common line GCL through the first switch group SG1, and thus, may be driven as the first non-contact touch electrode (or first non-contact touch sensing electrode).

The plurality of sub-electrodes CE2s1 to CE2s16 configured in each of the plurality of pixel blocks PB[2,y] to PB[x−1,y] disposed in the second edge portion EP2 of the display area AA may be commonly connected to the one group common line GCL through the second switch group SG2, and thus, may be driven as the second non-contact touch electrode (or second non-contact touch sensing electrode).

The plurality of sub-electrodes CE2s1 to CE2s16 configured in each of the plurality of pixel blocks PB[1,2] to PB[1,y−1] disposed in the third edge portion EP3 of the display area AA may be commonly connected to the one group common line GCL through the third switch group SG3, and thus, may be driven as the third non-contact touch electrode (or third non-contact touch sensing electrode).

The plurality of sub-electrodes CE2s1 to CE2s16 configured in each of the plurality of pixel blocks PB[x,2] to PB[x, y−1] disposed in the fourth edge portion EP4 of the display area AA may be commonly connected to the one group common line GCL through the fourth switch group SG4, and thus, may be driven as the fourth non-contact touch electrode (or fourth non-contact touch sensing electrode).

Referring to FIGS. 10, 14, 15, and 17, the second signal switching part 532 may include a plurality of second signal switches 532a configured to be electrically connected, through the plurality of data transmission lines DTL, to the pixel driving circuit PD disposed in each of the remaining pixel blocks PB except for the plurality of pixel blocks PB included in the second touch electrode part 220.

The plurality of second signal switches 532a may be included in each of a plurality of switch groups SG5 to SGnm. For example, the second signal switching part 532 may include fifth to n×m switch groups SG5 to SGnm. Each of the fifth to n×m switch groups SG5 to SGnm may include a plurality of second signal switches 532a.

Each of the fifth to n×m switch groups SG5 to SGnm may be configured to be individually connected to a plurality of pixel driving circuits PD configured in each of a plurality of pixel blocks PB included in each of a plurality of contact touch electrodes 211[1,1] to 211[n,m]. For example, the plurality of second signal switches 532a included in the fifth switch group SG5 may be individually connected, through the plurality of data transmission lines DTL, to the plurality of pixel driving circuits PD configured in each of the plurality of pixel blocks PB[2,2] to PB[4,4] used (or driven) as the first contact touch electrode 211[1,1] in the display area AA.

The pixel driving circuits PD provided in pixel blocks PB[1,1], PB[1,y], PB[x,1], and PB[x,y] disposed at corners of the display area AA may be connected to second signal switches 532a of adjacent switch groups.

Each of the plurality of second signal switches 532a included in each of the fifth to n×m switch groups SG5 to SGnm may be configured to supply the emission signal EM supplied from the emission signal generating part 520 to the corresponding pixel driving circuits PD through the corresponding data transmission lines DTL in the display period under the control of the signal control part 510. In the display period, one emission signal EM may be supplied to the pixel driving circuit PD through the second signal switch 532a and the data transmission line DTL, and may be converted into an anode voltage in the pixel driving circuit PD to be supplied to the light emitting device.

Each of the plurality of second signal switches 532a included in each of the fifth to n×m switch groups SG5 to SGnm may be configured to commonly connect the plurality of data transmission lines DTL to the one group common line GCL in the contact touch period or the non-contact touch period under the control of the signal control part 510. For example, the plurality of sub-electrodes CE2s1 to CE2s16 configured in each of the plurality of pixel blocks PB included in the second touch electrode part 220 of the display area AA may be commonly connected to the one group common line GCL, and thus, may be driven as a contact touch electrode. For example, the plurality of second signal switches 532a included in each of the fifth to n×m switch groups SG5 to SGnm may finally be connected to each of the plurality of contact touch electrodes 211.

Referring to FIGS. 10, 14, and 15, the line connection part 540 may be configured to connect the signal switching part 530 to the touch sensing part 550. The line connection part 540 may be configured to commonly supply an auxiliary driving signal ADS to the plurality of data transmission lines DTL connected to each of the plurality of non-contact touch electrodes, through the signal switching part 530 in the first touch mode. In addition, the line connection part 540 may be configured to commonly supply the touch driving signal TDS to the plurality of data transmission lines DTL connected to each of the plurality of contact touch electrodes, through the signal switching part 530 in the second touch mode.

The line connection part 540 may be configured to connect a first group among a plurality of group common lines GCL to the touch sensing part 550 in the contact touch period under the control of the signal control part 510. For example, in the contact touch period, the line connection part 540 may be configured to individually connect the first group among the plurality of group common lines GCL to a plurality of sensor connection lines SCL connected to the touch sensing part 550. For example, in the contact touch period, the line connection part 540 may be configured to commonly supply the auxiliary driving signal ADS to a second group except for the first group among the plurality of group common lines GCL.

The line connection part 540 may be configured to commonly supply the touch driving signal TDS to the first group among the plurality of group common lines GCL, and to connect the second group except for the first group among the plurality of group common lines GCL to the touch sensing part 550, in the non-contact touch period under the control of the signal control part 510. For example, in the non-contact touch period, the line connection part 540 may be configured to commonly supply the touch driving signal TDS to the first group among the plurality of group common lines GCL, and to individually connect the second group among the plurality of group common lines GCL to a plurality of sensor connection lines SCL.

The line connection part 540 according to one or more embodiments of the present disclosure may include a first line switching part 541 and a second line switching part 542.

Referring to FIGS. 10, 14 to 16, the first line switching part 541 may include a plurality of first line switches 541a.

The plurality of first line switches 541a may be configured to individually connect the second group among the plurality of group common lines GCL to the plurality of sensor connection lines SCL. The plurality of first line switches 541a may be configured to individually connect the plurality of group common lines GCL connected to the first signal switching part 531 among the plurality of group common lines GCL to the plurality of sensor connection lines SCL.

The plurality of first line switches 541a may be electrically connected between the plurality of group common lines GCL connected to the first signal switching part 531 and the plurality of sensor connection lines SCL. For example, one first line switch 541a may be electrically connected between one group common line GCL and one sensor connection line SCL.

Each of the plurality of first line switches 541a may be configured to individually connect the plurality of group common lines GCL connected to the first signal switching part 531 and the plurality of sensor connection lines SCL, in the non-contact touch period under the control of the signal control part 510. Accordingly, each of the first to fourth switch groups SG1, SG2, SG3, and SG4 of the first signal switching part 531 may be individually connected to the plurality of sensor connection lines SCL. For example, each of the plurality of first line switches 541a may be turned on only in the non-contact touch period based on a hover enable signal.

The plurality of sub-electrodes CE2s1 to CE2s16 configured in each of the pixel blocks PB disposed at the edge portions EP1, EP2, EP3, and EP4 of the display area AA may be commonly connected to one group common line GCL and one sensor connection line SCL, and thus, may be driven as the non-contact touch electrode (or non-contact touch sensing electrode). For example, the one sensor connection line SCL may be commonly connected to the plurality of sub-electrodes CE2s1 to CE2s16 through one first line switch 541a, one group common line GCL, the plurality of first signal switches 531a, the plurality of data transmission lines DTL, the third switch 433 of the pixel driving circuits PD provided in the plurality of pixel blocks PB, and the cathode electrode driving part 420. Accordingly, the plurality of sub-electrodes CE2s1 to CE2s16 may be used (or driven) as one non-contact touch electrode (or non-contact sensing electrode).

The first line switching part 541 may further include a plurality of first line connection switches 541b and a first signal supply switch 541c.

The plurality of first line connection switches 541b may be configured to commonly connect the plurality of group common lines GCL connected to the first signal switching part 531. The plurality of first line connection switches 541b may be electrically connected between the plurality of group common lines GCL. Each of the plurality of first line connection switches 541b may be configured to commonly connect the plurality of group common lines GCL connected to the first signal switching part 531 in the contact touch period under the control of the signal control part 510. For example, in the contact touch period, the plurality of group common lines GCL connected to the first signal switching part 531 may be electrically connected to each other by the plurality of first line connection switches 541b, and thus, may be driven as one group common line.

The first signal supply switch 541c may be configured to supply the auxiliary driving signal ADS to the plurality of group common lines GCL. For example, the first signal supply switch 541c may supply the auxiliary driving signal ADS to any one of the plurality of group common lines GCL in the contact touch period. Accordingly, in the contact touch period, the plurality of group common lines GCL may be commonly connected by the plurality of first line connection switches 541b and commonly supplied with the auxiliary driving signal ADS through the first signal supply switch 541c.

The plurality of first line connection switches 541b and the first signal supply switch 541c may each be turned on simultaneously only in the contact touch period in response to the touch synchronization signal.

Referring to FIGS. 10, 14, 15, and 17, the second line switching part 542 may include a plurality of second line switches 542a.

The plurality of second line switches 542a may be configured to individually connect a first group among the plurality of group common lines GCL to the plurality of sensor connection lines SCL. Each of the plurality of second line switches 542a may be configured to individually connect the plurality of group common lines GCL connected to the second signal switching part 532 among the plurality of group common lines GCL to the plurality of sensor connection lines SCL.

The plurality of second line switches 542a may be electrically connected between the plurality of group common lines GCL connected to the second signal switching part 532 and the plurality of sensor connection lines SCL. For example, one second line switch 542a may be electrically connected between one group common line GCL and one sensor connection line SCL.

Each of the plurality of second line switches 542a may be configured to individually connect the plurality of group common lines GCL connected to the second signal switching part 532 and the plurality of sensor connection lines SCL in the non-contact touch period under the control of the signal control part 510. Accordingly, each of the fifth to n×m switch groups SG5 to SGnm of the second signal switching part 532 may be individually connected to the plurality of sensor connection lines SCL. For example, each of the plurality of second line switches 542a may be turned on only in the contact touch period in response to the touch synchronization signal.

A plurality of sub-electrodes CE2s1 to CE2s16 configured in each of the plurality of pixel blocks PB disposed at the intermediate portion of the display area AA may be commonly connected to the one group common line GCL and one sensor connection line SCL, and thus, may be driven as a contact touch electrode. For example, the one sensor connection line SCL may be commonly connected to the plurality of sub-electrodes CE2s1 to CE2s16 through the second line switch 542a, the group common line GCL, the plurality of second signal switches 532a, the plurality of data transmission lines DTL, the third switch 433 of the pixel driving circuits PD provided in each of the plurality of pixel blocks PB, and the cathode electrode driving part 420. Accordingly, the plurality of sub-electrodes CE2s1 to CE2s16 may be used (or driven) as one contact touch electrode.

The second line switching part 542 may further include a plurality of second line connection switches 542b and a second signal supply switch 542c.

The plurality of second line connection switches 542b may be configured to commonly connect the plurality of group common lines GCL connected to the second signal switching part 532. The plurality of second line connection switches 542b may be electrically connected between the plurality of group common lines GCL. Each of the plurality of second line connection switches 542b may be configured to commonly connect the plurality of group common lines GCL connected to the second signal switching part 532 in the non-contact touch period under the control of the signal control part 510. For example, in the non-contact touch period, the plurality of group common lines GCL connected to the second signal switching part 532 may be electrically connected to each other by the plurality of second line connection switches 542b, and thus, may be driven as one group common line.

The second signal supply switch 542c may be configured to supply the auxiliary driving signal ADS to the plurality of group common lines GCL. For example, the second signal supply switch 542c may supply the auxiliary driving signal ADS to any one of the plurality of group common lines GCL in the non-contact touch period. Accordingly, in the non-contact touch period, the plurality of group common lines GCL may be commonly connected by the plurality of second line connection switches 542b and commonly supplied with the touch driving signal TDS through the second signal supply switch 542c. Therefore, in the non-contact touch period, all of the sub-electrodes CE2s1 to CE2s16 of all of the second electrodes CE2 disposed in all the pixel blocks PB included in the first touch electrode part 210 except for the second touch electrode part 220 of the display area AA may be driven as one hover touch driving electrode to which the touch driving signal TDS is supplied. For example, in the non-contact touch period, all of the sub-electrodes CE2s1 to CE2s16 of the second electrodes CE2 disposed in the intermediate portion of the display area AA may be driven as the one hover touch driving electrode to which the touch driving signal TDS is supplied, and the one hover touch driving electrode may form mutual capacitance with each of the plurality of non-contact touch electrodes driven at the edge portion of the display area AA. Therefore, a user's non-contact touch (or hover touch) may be sensed based on a change in the mutual capacitance between each of the plurality of non-contact touch electrodes and the one hover touch driving electrode.

The plurality of second line connection switches 542b and the second signal supply switch 542c may each be turned on only in the non-contact touch period in response to the hover enable signal.

Referring to FIGS. 10, 14, and 15, the touch sensing part 550 may be configured to be electrically connected to the plurality of sensor connection lines SCL. The touch sensing part 550 may be configured to generate touch raw data corresponding to touch sensing signals (or changes in capacitance) supplied from the pixel driving circuits PD through each of the plurality of sensor connection lines SCL. For example, the touch sensing part 550 may be configured to provide the touch raw data (or sensing raw data) to the signal control part 510 or the host control part 600. For example, the touch sensing part 550 may provide the touch raw data to the signal control part 510, in this case, the signal control part 510 may be configured to provide the plurality of touch raw data which is provided from the touch sensing part 550 to the host control part 600, but is not limited thereto. For example, the signal control part 510 may be configured to generate user touch information based on the plurality of touch raw data which is provided from the touch sensing part 550, and to provide the user touch information to the host control part 600.

The touch sensing part 550 according to one or more embodiments of the present disclosure may include a first touch sensing part 551 and a second touch sensing part 552.

Referring to FIGS. 10 and 14 to 16, the first touch sensing part 551 may be configured to sense a non-contact touch based on touch sensing signals (or changes in capacitance) supplied through each of data transmission lines DTL of a second group among the plurality of data transmission lines DTL. The first touch sensing part 551 may include a plurality of first touch sensing circuits 551a.

The plurality of first touch sensing circuits 551a may be configured to be individually connected to a second group among the plurality of sensor connection lines SCL. The plurality of first touch sensing circuits 551a may be configured to be individually connected to the plurality of sensor connection lines SCL connected to the first line switching part 541 among the plurality of sensor connection lines SCL.

Each of the plurality of first touch sensing circuits 551a may be configured to generate second touch raw data (or hover touch raw data) HTdata corresponding to the touch sensing signals (or changes in capacitance) supplied from the pixel driving circuits PD through the corresponding sensor connection line SCL in the non-contact touch period. For example, the second touch raw data HTdata generated in each of the first touch sensing circuits 551a may be provided to the host control part 600 or the signal control part 510.

Each of the plurality of first touch sensing circuits 551a may include a touch sensor, an analog-to-digital converter, and a touch controller, but is not limited thereto.

The touch sensor may be configured to output an analog sensing signal corresponding to touch sensing signals (or changes in capacitance) supplied from the pixel driving circuits PD through the sensor connection lines SCL. For example, the touch sensor may be an analog front-end (AFE) circuit, but is not limited thereto. The analog-to-digital converter may convert the analog sensing signal output from the touch sensor into digital data to output the second touch raw data HTdata. The touch controller may be configured to control the touch sensor and the analog-to-digital converter.

In the non-contact touch period, if there is no a user's non-contact touch, the magnitude of the voltage charged in the capacitor of the touch sensor may be within a preset reference range. In contrast, if there is a user's non-contact touch in the non-contact touch period, the magnitude of the voltage charged in the capacitor of the touch sensor may exceed the preset reference range. Accordingly, the second touch raw data HTdata output from the analog-to-digital converter may vary depending on the magnitude of the voltage charged in the capacitor.

Referring to FIGS. 10, 14, 15, and 17, the second touch sensing part 552 may be configured to sense a contact touch based on touch sensing signals (or changes in capacitance) supplied through each of the data transmission lines DTL of a first group among the plurality of data transmission lines DTL. The second touch sensing part 552 may include a plurality of second touch sensing circuits 552a.

The plurality of second touch sensing circuits 552a may be configured to be individually connected to the first group among the plurality of sensor connection lines SCL. The plurality of second touch sensing circuits 552a may be configured to be individually connected to the plurality of sensor connection lines SCL connected to the second line switching part 542 among the plurality of sensor connection lines SCL.

Each of the plurality of second touch sensing circuits 552a may be configured to generate first touch raw data (or contact touch raw data) CTdata corresponding to touch sensing signals (or changes in capacitance) supplied from the pixel driving circuits PD through the corresponding sensor connection line SCL in the contact touch period. For example, the first touch raw data CTdata generated in each of the plurality of second touch sensing circuits 552a may be provided to the host control part 600 or the signal control part 510.

Each of the plurality of second touch sensing circuits 552a according to one or more embodiments of the present disclosure may include a comparator (or amplifier) having three terminals. The three terminals of the comparator may include a first terminal, a second terminal, and a third terminal.

The first terminal may receive the touch driving signal TDS, the second terminal may be connected to an analog-to-digital converter configured to convert analog information related to touch into digital information, and the third terminal may be connected to a sensor connection line SCL. For example, a capacitor may be connected between the second terminal and the third terminal.

In the contact touch period, the touch driving signal TDS may be supplied to the first terminal of the comparator, and the touch driving signal TDS supplied to the first terminal of the comparator may be finally transmitted to the sub-electrodes CE2s1 to CE2s16 of the second electrode CE2 through the third terminal, the sensor connection line SCL, and the pixel driving circuit PD.

In the contact touch period, if there is no a user's touch, the magnitude of the voltage charged in the capacitor provided between the second terminal and the third terminal of the comparator may be included in the preset reference range. In contrast, if there is a user' touch in the contact touch period, the magnitude of the voltage charged in the capacitor may exceed the preset reference range. Accordingly, the first touch raw data CTdata output from the analog-to-digital converter may vary depending on the magnitude of the voltage charged in the capacitor.

As described above, the display apparatus according to one or more embodiments of the present disclosure may drive the second electrodes CE2 of pixel blocks PB configured in the display area AA as a plurality of contact touch electrodes to sense a user's contact touch. Furthermore, the display apparatus according to one or more embodiments of the present disclosure may drive the second electrodes CE2 of pixel blocks PB configured in the edge portions of the display area AA as non-contact touch driving electrodes, and may drive the second electrodes CE2 of pixel blocks PB configured in the edge portions of the display area AA as non-contact touch sensing electrodes, thereby sensing a user's non-contact touch without a separate non-contact touch electrode (or hover touch electrode). In addition, the display apparatus according to one or more embodiments of the present disclosure may drive the second electrodes CE2 of pixel blocks PB configured in the display area AA as a plurality of contact touch electrodes and may drive the second electrodes CE2 of pixel blocks PB configured in the edge portions of the display area AA as touch guard electrodes (or touch shield electrodes), thereby minimizing, at least reducing or preventing a reduction in touch sensitivity (or performance) and improving touch sensitivity (or performance) at the edge portions of the display area AA.

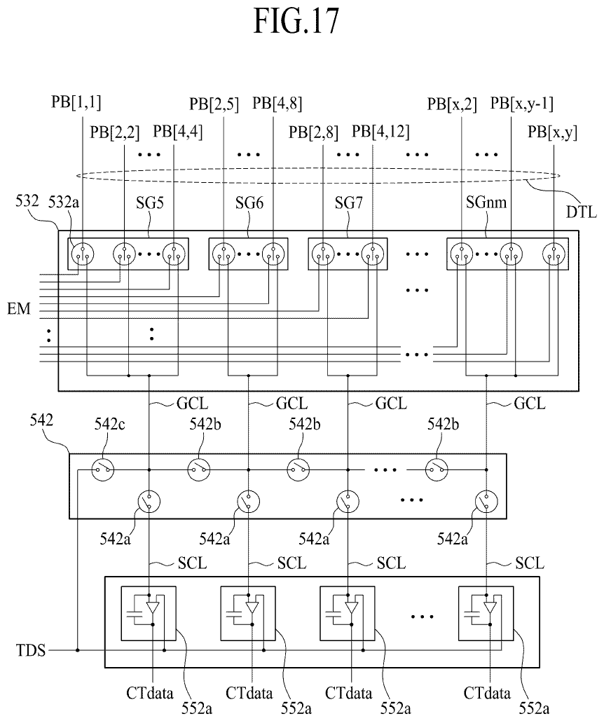

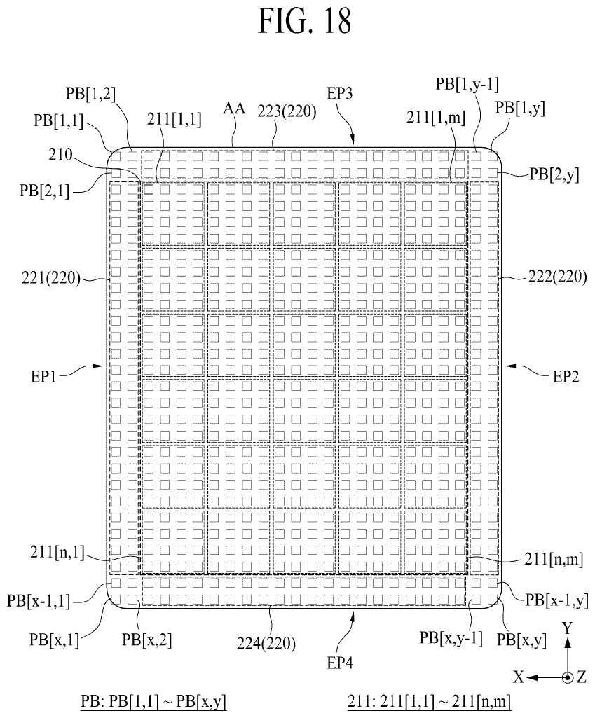

FIG. 18 is a diagram illustrating first and second touch electrode parts according to one or more embodiments of the present disclosure. FIG. 18 illustrates one or more embodiments where the first and second touch electrode parts described above with reference to FIG. 10 has been modified.

Referring to FIG. 18, the display apparatus according to one or more embodiments of the present disclosure may include a first touch electrode part 210 and a second touch electrode part 220 disposed (or configured) in the display area AA.

The first touch electrode part 210 may include the remaining pixel blocks PB except for pixel blocks PB disposed (or configured) in each of the first to fourth edge portions EP1, EP2, EP3, and EP4 of the display area AA among the plurality of pixel blocks PB[1,1] to PB[x,y].

The first touch electrode part 210 may include a plurality of contact touch electrodes (or contact touch areas) 211. For example, the first touch electrode part 210 may include first to n×m contact touch electrodes 211[1,1] to 211[n,m].

Each of the plurality of contact touch electrodes 211[1,1] to 211[n,m] may have the same size (or area). For example, each of the contact touch electrodes 211[1,1] to 211[n,m] may include the same number of pixel blocks PB. For example, each of the contact touch electrodes 211[1,1] to 211[n,m] may include sixteen pixel blocks PB disposed in a matrix of four rows and four columns, but is not limited thereto. For example, sub-electrodes of the second electrodes CE2 disposed in each of the sixteen pixel blocks PB disposed in a matrix of four rows and four columns may form one contact touch electrode 211 or may be driven as one contact touch electrode 211. For example, the first touch electrode part 210 may include a plurality of contact touch electrodes 211 (or contact touch areas) driven by some of the plurality of sub-electrodes of the second electrodes CE2.

Except that each of the plurality of contact touch electrodes 211[1,1] to 211[n,m] has the same size, they are substantially identical to the plurality of contact touch electrodes 211[1,1] to 211[n,m] described above with reference to FIG. 10, and thus a detailed description thereof is omitted. Accordingly, each of the plurality of contact touch electrodes 211[1,1] to 211[n,m] may be driven as the contact touch electrode in the first touch mode and as the non-contact touch driving electrode (or hover touch driving electrode) in the second touch mode, by the switching operations of each of the cathode electrode driving part 420 and the switching part 430 of the pixel driving circuit PD and the switching operations of the signal switching part 530 and the line connection part 540 of the driving integrated circuit 311 described above with reference to FIGS. 14 to 17, and thus, a detailed description thereof is omitted.

The second touch electrode part 220 may include a plurality of non-contact touch electrodes (or non-contact touch areas) 221, 222, 223, and 224. For example, the second touch electrode part 220 may include a plurality of non-contact touch electrodes 221, 222, 223, and 224 driven by at least some other sub-electrodes of the second electrodes CE2. The second touch electrode part 220 may include first to fourth non-contact touch electrodes 221, 222, 223, and 224.

The first non-contact touch electrode 221 may be disposed (or configured) in the first edge portion EP1 of the display area AA. The plurality of second electrodes CE2 configured in pixel blocks PB included in the two pixel block columns disposed in the first edge portion EP1 of the display area AA may be driven as the first non-contact touch electrode 221. For example, the plurality of second electrodes CE2 configured in pixel blocks PB[3,1] to PB[x−2,1] and PB[3,2] to PB[x−2,2] disposed in the third to (x−2)^{th} rows among the first and second pixel block columns of the display area AA may be driven as the first non-contact touch electrode 221 or as one first non-contact touch electrode 221.

The second non-contact touch electrode 222 may be disposed (or configured) in the second edge portion EP2 of the display area AA. The plurality of second electrodes CE2 configured in pixel blocks PB included in the two pixel block columns disposed in the second edge portion EP2 may be driven as the second non-contact touch electrode 222. For example, the plurality of second electrodes CE2 configured in pixel blocks PB[3,y−1] to PB[x−2,y−1] and PB[3,y] to PB[x−2,y] disposed in the third to (x−2)^{th} rows among the (y−1)^{th} and y^{th} pixel block columns of the display area AA may be driven as the second non-contact touch electrode 222 or as one second non-contact touch electrode 222.

The third non-contact touch electrode 223 may be disposed (or configured) in the third edge portion EP3 of the display area AA. The plurality of second electrodes CE2 configured in pixel blocks PB included in the two pixel block rows disposed in the third edge portion EP3 may be driven as the third non-contact touch electrode 223. For example, the plurality of second electrodes CE2 configured in pixel blocks PB[1,3] to PB[1,y−2] and PB[2,3] to PB[2,y−2] disposed in the third to (y−2)^{th} columns among the first and second pixel block rows of the display area AA may be driven as the third non-contact touch electrode 223 or as one third non-contact touch electrode 223.

The fourth non-contact touch electrode 224 may be disposed (or configured) in the fourth edge portion EP4 of the display area AA. The plurality of second electrodes CE2 configured in pixel blocks PB[x−1,3] to PB[x−1,y−2] and PB[x,3] to PB[x,y−2] included in the third to (y−2)^{th} columns among the (x−1)^{th} and x^{th} pixel block rows of the display area AA may be driven as the fourth non-contact touch electrode 224 or as one fourth non-contact touch electrode 224.

Except that each of the plurality of (or first to fourth) non-contact touch electrodes 221, 222, 223, and 224 has a larger size (or wider area) than the plurality of (or first to fourth) non-contact touch electrodes 221, 222, 223, and 224 described above with reference to FIG. 10, each of the plurality of (or first to fourth) non-contact touch electrodes 221, 222, 223, and 224 is substantially the same as the plurality of (or first to fourth) non-contact touch electrodes 221, 222, 223, and 224 described above with reference to FIG. 10, and thus, a detailed description is omitted. Accordingly, each of the plurality of (or first to fourth) non-contact touch electrodes 221, 222, 223, and 224 may configure (or form) as a hover touch sensing electrode or may be driven as a hover touch sensing electrode in the second touch mode, by the switching operations of the cathode electrode driving part 420 and the switching part 430 of the pixel driving circuit PD and the switching operations of the signal switching part 530 and the line connection part 540 of the driving integrated circuit 311 described above with reference to FIGS. 14 to 17, and thus, a detailed description is omitted. For example, each of the first to fourth non-contact touch electrodes 221, 222, 223, and 224 may be driven as a hover touch sensing electrode for sensing a user's non-contact touch at the edge portions of the display area AA in the second touch mode.

Each of the plurality of (or first to fourth) non-contact touch electrodes 221, 222, 223, and 224 may be used (or driven) as a touch guard electrode receiving an auxiliary driving signal or a touch shield electrode receiving a constant direct-current (DC) voltage in the first touch mode, as described above with reference to FIGS. 14 to 17.

As described above, the display apparatus according to one or more embodiments of FIG. 18 may have the same effects as the display apparatus according to one or more other embodiments of the present disclosure, and as the size (or area) of the non-contact touch electrodes increases, the touch sensitivity (or performance) for the user's non-contact touch (or hover touch) may be further improved.

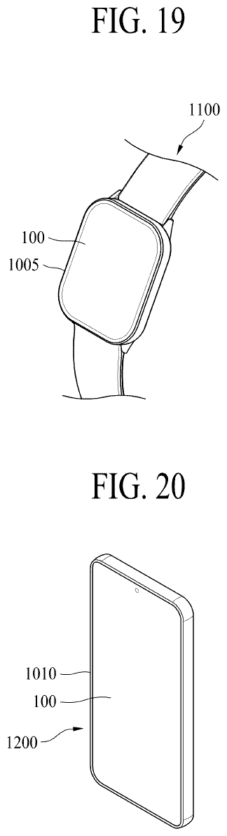

FIGS. 19 to 22 are diagrams illustrating an apparatus to which a display apparatus is applied according to one or more embodiments of the present disclosure.

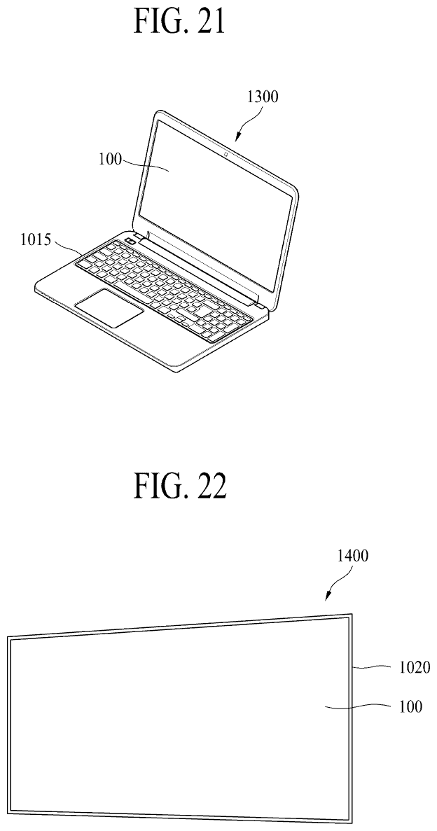

Referring to FIGS. 19 to 22, the display apparatus according to one or more embodiments of the present disclosure may be applied to or included in various apparatuses or electronic apparatuses. For example, the various electronic apparatuses may include a wearable device 1100 illustrated in FIG. 19, a mobile device 1200 illustrated in FIG. 20, a notebook 1300 illustrated in FIG. 21, and a monitor or TV 1400 illustrated in FIG. 22, but is not limited thereto.

Each of the wearable device 1100, the mobile device 1200, the notebook 1300, and the monitor or TV 1400 may include a case part 1005, 1010, 1015, and 1020, and the display apparatus 1000 according to the above-described embodiments of the present disclosure. Therefore, descriptions to the display apparatus 1000 are omitted. The description with reference above to FIGS. 1 to 18 may be included in the description of FIGS. 19 to 22.

For example, the display apparatus according to one or more embodiments of the present disclosure may be applied to a mobile device, a video phone, a smart watch, a watch phone, a wearable apparatus, a foldable apparatus, a rollable apparatus, a bendable apparatus, a flexible apparatus, a curved apparatus, a sliding apparatus, a variable apparatus, an electronic notebook, an electronic book, a PMP (a portable multimedia player), a PDA (a personal digital assistant), an MP3 (MPEG Audio Layer 3) player, a mobile medical device, a desktop personal computer, a laptop personal computer, a netbook computer, a workstation, a navigation, a vehicle display apparatus, a theater display apparatus, a television, a wallpaper device, a signage device, a game device, a notebook, a monitor, a camera, a camcorder, or a home appliances, or the like.

It will be apparent to those skilled in the art that various modifications and variations may be made in the present disclosure without departing from the technical idea or scope of the disclosures. Thus, it is intended that the present disclosure covers the modifications and variations of this disclosure provided that within the scope of the claims and their equivalents.

What is claimed is:

1. A display apparatus, comprising:
a substrate including a display area;
a first touch electrode part disposed in an intermediate portion of the display area;
a second touch electrode part disposed along an edge portion of the display area; and
a driving circuit part configured to:
sense a contact touch of a user through the first touch electrode part, and
sense a non-contact touch of the user through the second touch electrode part.

2. The display apparatus of claim 1, further comprising a plurality of pixel blocks disposed in the display area,
wherein each of the plurality of pixel blocks comprises:
a pixel driving circuit;
an insulating layer covering the pixel driving circuit;
a plurality of first electrodes electrically connected to the pixel driving circuit;
a plurality of light emitting devices electrically connected to each of the plurality of first electrodes; and
a second electrode electrically connected to each of the plurality of light emitting devices, the second electrode including a plurality of sub-electrodes spaced apart from each other,
wherein the first touch electrode part comprises a plurality of contact touch electrodes driven by a portion of the plurality of sub-electrodes, and
wherein the second touch electrode part comprises a plurality of non-contact touch electrodes driven by at least another portion of the plurality of sub-electrodes.

3. The display apparatus of claim 2, wherein the driving circuit part is configured to:
sense the contact touch through the plurality of contact touch electrodes in a first touch mode; and
commonly supply a touch driving signal to the plurality of contact touch electrodes and sense the non-contact touch through the plurality of non-contact touch electrodes in a second touch mode.

4. The display apparatus of claim 2, wherein, in a first touch mode, the driving circuit part is configured to apply an auxiliary driving signal to the plurality of non-contact touch electrodes and to apply a touch driving signal to each of the plurality of contact touch electrodes to sense the contact touch through each of the plurality of contact touch electrodes.

5. The display apparatus of claim 4, wherein the auxiliary driving signal is any one of a direct current voltage, a ground voltage, and the touch driving signal.

6. The display apparatus of claim 2, wherein:
in a first touch mode or a second touch mode, the plurality of sub-electrodes configured in the pixel blocks disposed in the intermediate portion of the display area among the plurality of pixel blocks are driven as the contact touch electrodes, and
in the first touch mode or the second touch mode, the plurality of sub-electrodes configured in the pixel blocks disposed in the edge portion of the display area among the plurality of pixel blocks are driven as the non-contact touch electrodes.

7. The display apparatus of claim 6, wherein the driving circuit part is configured to:
apply, in the first touch mode, a touch driving signal to each of the plurality of contact touch electrodes through the pixel driving circuit of the pixel blocks and sense the contact touch through the plurality of contact touch electrodes and the pixel driving circuit of the pixel blocks; and
simultaneously apply, in the second touch mode, the touch driving signal to the plurality of contact touch electrodes through the pixel driving circuit of the pixel blocks and sense the non-contact touch through each of the plurality of non-contact touch electrodes and the pixel driving circuit of the pixel blocks.

8. The display apparatus of claim 2, wherein each of the plurality of contact touch electrodes has a same size, or some of the plurality of contact touch electrodes have different sizes.

9. The display apparatus of claim 8, wherein:
the display area comprises a plurality of pixel block rows and a plurality of pixel block columns including the plurality of pixel blocks, a first edge portion adjacent to a first side of the substrate, a second edge portion adjacent to a second side of the substrate opposite to the first side of the substrate, a third edge portion adjacent to a third side of the substrate, and a fourth edge portion adjacent to a fourth side of the substrate opposite to the third side of the substrate,
the plurality of sub-electrodes configured in each of the pixel blocks disposed in the intermediate portion of the display area except for the first to fourth edge portions of the display area are driven as the plurality of contact touch electrodes,
the plurality of sub-electrodes configured in the pixel blocks included in one or more pixel block columns disposed in the first edge portion of the display area are driven as a first non-contact touch electrode among the plurality of non-contact touch electrodes,
the plurality of sub-electrodes configured in the pixel blocks included in one or more pixel block columns disposed in the second edge portion of the display area are driven as a second non-contact touch electrode among the plurality of non-contact touch electrodes,
the plurality of sub-electrodes configured in the pixel blocks included in one or more pixel block rows disposed in the third edge portion of the display area are driven as a third non-contact touch electrode among the plurality of non-contact touch electrodes, and
the plurality of sub-electrodes configured in the pixel blocks included in one or more pixel block rows disposed in the fourth edge portion of the display area are driven as a fourth non-contact touch electrode among the plurality of non-contact touch electrodes.

10. The display apparatus of claim 2, wherein:
the driving circuit part is electrically connected to the pixel driving circuit disposed in each of the plurality of pixel blocks through a plurality of data transmission lines,
the pixel driving circuit is configured to sequentially apply a cathode voltage to the plurality of sub-electrodes disposed in each of the plurality of pixel blocks in a display mode, and the pixel driving circuit is configured to commonly connect the plurality of sub-electrodes to corresponding data transmission lines among the plurality of data transmission lines in a first touch mode or a second touch mode, and
the plurality of light emitting devices connected to each of the plurality of sub-electrodes emit light when the cathode voltage is applied.

11. The display apparatus of claim 10, wherein the pixel driving circuit comprises:
a sub-pixel driving part configured to supply an anode voltage corresponding to an emission signal supplied from the driving circuit part to the plurality of first electrodes, the emission signal including a duty-on period and a duty-off period,
a cathode electrode driving part configured to supply the cathode voltage or a touch driving signal to the plurality of sub-electrodes, and
a switching part configured to connect a corresponding data transmission line among the plurality of data transmission lines to the cathode electrode driving part or the sub-pixel driving part.

12. The display apparatus of claim 11, wherein the switching part comprises:
a first switch configured to supply the cathode voltage to the cathode electrode driving part in the display mode,
a second switch configured to electrically connect the corresponding data transmission line to the sub-pixel driving part in the display mode, and the second switch configured to electrically disconnect the corresponding data transmission line from the sub-pixel driving part in the first touch mode or the second touch mode, and
a third switch configured to electrically disconnect the corresponding data transmission line from the cathode electrode driving part in the display mode, and electrically connect the corresponding data transmission line to the cathode electrode driving part in the first touch mode or the second touch mode.

13. The display apparatus of claim 11, wherein the driving circuit part comprises:
an emission signal generating part configured to generate the emission signal based on image data,
a touch sensing part configured to sense a touch sensing signal through each of the plurality of data transmission lines,
a signal switching part configured to supply the emission signal to each of the plurality of data transmission lines or connect each of the plurality of data transmission lines to the touch sensing part, and
a line connection part connected between the signal switching part and the touch sensing part.

14. The display apparatus of claim 13, wherein the signal switching part is configured to:
supply the emission signal to each of the plurality of data transmission lines in the display mode;
electrically connect each of a first group of data transmission lines, among the plurality of data transmission lines connected to each of the plurality of contact touch electrodes, to the touch sensing part through the line connection part in the first touch mode; and
electrically connect each of a second group of data transmission lines, among the plurality of data transmission lines connected to each of the plurality of non-contact touch electrodes, to the touch sensing part through the line connection part in the second touch mode.

15. The display apparatus of claim 14, wherein the touch sensing part comprises:
a first touch sensing part configured to sense the non-contact touch based on the touch sensing signal supplied through each of the data transmission lines of the second group among the plurality of data transmission lines; and
a second touch sensing part configured to sense the contact touch based on the touch sensing signal supplied through each of the data transmission lines of the first group among the plurality of data transmission lines.

16. The display apparatus of claim 15, wherein the line connection part is configured to commonly supply an auxiliary driving signal, in the first touch mode, to the plurality of data transmission lines connected to each of the plurality of non-contact touch electrodes through the signal switching part.

17. The display apparatus of claim 15, wherein the line connection part is configured to commonly supply the touch driving signal, in the second touch mode, to the plurality of data transmission lines connected to each of the plurality of contact touch electrodes through the signal switching part.

18. The display apparatus of claim 2, further comprising:
a plurality of banks in the insulating layer;
a plurality of connection electrodes in each of the plurality of banks, wherein the plurality of connection electrodes are electrically connected to a corresponding pixel driving circuit of the plurality of pixel driving circuits; and
a plurality of bonding pads in each of the plurality of connection electrodes, and
wherein each of the plurality of light emitting devices comprises:
a first terminal electrically connected to a corresponding bonding pad of the plurality of bonding pads; and
a second terminal electrically connected to the second electrode.

19. The display apparatus of claim 18, further comprising an optical layer configured on the insulating layer so as to surround lateral surfaces of each of the plurality of light emitting devices and lateral surfaces of each of the plurality of banks,
wherein each of the plurality of light emitting devices is a micro light emitting device or a micro light emitting diode chip.

20. The display apparatus of claim 19, wherein the optical layer comprises:
a first optical layer configured to surround side portions of each of the plurality of light emitting devices and the plurality of banks in a region between the second electrode and the insulating layer;
a second optical layer configured to surround a side portion of the first optical layer; and
a third optical layer disposed on the second electrode so as to overlap the plurality of light emitting devices and the first optical layer.
